(19) United States
(12) Patent Application Publication
(10) Pub. No.: US 2025/0309924 A1
(43) Pub. Date: Oct. 2, 2025

(54) SINGLE-PORT MULTI-TOUCH (SPMT) ANTENNA FOR REALIZING MULTIPLE TOUCH BUTTONS AND DIRECTIONAL SWIPE GESTURES

(71) Applicant: Amazon Technologies, Inc., Seattle, WA (US)

(72) Inventors: Sumitra Dey, Sunnyvale, CA (US); Nicholas Evangelos Buris, Chicago, IL (US); Jason Wang, Belmont, CA (US); Mukund Ranga Thyagarajan, Dublin, CA (US); Divya Naveenan, Sunnyvale, CA (US)

(21) Appl. No.: 18/622,469

(22) Filed: Mar. 29, 2024

(51) Int. Cl. H04B 1/00; G06F 3/01; H01Q 9/04; H04B 1/44

(52) U.S. Cl. CPC H04B 1/0007; G06F 3/017; H01Q 9/0414; H04B 1/44

(57) ABSTRACT

Technologies directed to antennas as sensors for touch and hover events are described. A wireless device can include a processing device with classification logic and a detection circuit located in a radio frequency (RF) path between a radio and an SPMT antenna. The wireless device can sample the analog voltage signal at a plurality of frequencies over a period of time to obtain digital data. The classification logic uses the digital data to classify one or more touch points caused by a presence of an object in proximity to the SPMT antenna over the period of time as a touch event or a gesture event. The processing device can perform an action in response to the touch event or gesture event.

### BACKGROUND

A large and growing population of users is enjoying entertainment through the consumption of digital media items, such as music, movies, images, electronic books, and so on. The users employ various electronic devices to consume such media items. Among these electronic devices (referred to herein as endpoint devices, user devices, clients, client devices, or user equipment) are electronic book readers, cellular telephones, Personal Digital Assistants (PDAs), portable media players, tablet computers, netbooks, laptops, and the like. These electronic devices wirelessly communicate with a communications infrastructure to enable the consumption of digital media items. In order to communicate with other devices wirelessly, these electronic devices include one or more antennas. The devices often provide for touch-based user interactions to control the functionality of the device (e.g., playback functionality, volume control, etc.)

### BRIEF DESCRIPTION OF DRAWINGS

The present inventions will be understood more fully from the detailed description given below and from the accompanying drawings of various embodiments of the present invention, which, however, should not be taken to limit the present invention to the specific embodiments, but are for explanation and understanding only.

FIG. 1 is a block diagram of a wireless device with a single-port multi-touch (SPMT) antenna, classification logic, and detection circuit to detect touches at multiple touch points for a touch event or a gesture event caused by an object in proximity to the SPMT antenna according to at least one embodiment.

FIG. 2 is a schematic diagram of a detection circuit that detects and converts an amount of reflected power in a radio frequency (RF) path to a voltage waveform according to at least one embodiment.

FIG. 3 is a graph illustrating an output signal of a detection circuit during normal communication transmissions of a radio according to at least one embodiment.

FIG. 4 illustrates graphs of a voltage response in free space and in the presence of a object using a remote SPMT antenna and a graph of a reflection signal response in free space in the presence of a object using the remote SPMT antenna according to at least one embodiment.

FIG. 5 illustrates graphs of antenna impedance change, return loss, and detector circuit output signals according to at least one embodiment.

FIG. 6 is a graph showing analog-to-digital converter (ADC) steps for different use cases according to at least one embodiment.

FIG. 7 illustrates multiple gestures and corresponding actions according to at least one embodiment.

FIG. 8 illustrates multiple unique touch points identified on and around an antenna aperture of an SPMT antenna, according to at least one embodiment.

FIG. 9 illustrates an example directional swipe event between multiple touch points according to at least one embodiment.

FIG. 10 illustrates an example single dipole antenna with end asymmetries according to at least one embodiment.

FIG. 11A illustrates an example two-layer, cross-dipole antenna with end asymmetries according to at least one embodiment.

FIG. 11B illustrates different views of the example two-layer, cross-dipole antenna of FIG. 11A with end asymmetries according to at least one embodiment.

FIG. 11C illustrates a bottom view and a perspective view of an example two-layer, cross-dipole antenna with end asymmetries according to at least one embodiment.

FIG. 12 illustrates example data streams that are fed into an event mapper and stored in an event history for the two-layer, cross-dipole antenna of FIG. 11A with four virtual buttons according to at least one embodiment.

FIG. 13 illustrates ADC responses for single touch events at four virtual buttons according to at least one embodiment.

FIG. 14 illustrates a graph tracking deviations of output data from baseline data at three channels according to at least one embodiment.

FIG. 15 illustrates an example Truth Table with the quantized voltage levels (VTT) at three channels for twenty-five touch configurations according to at least one embodiment.

FIG. 16 illustrates an example dual dipole butterfly antenna with arm asymmetries according to at least one embodiment.

FIG. 17 illustrates an example single planar inverted F antenna (PIFA) with induced gaps according to at least one embodiment.

FIG. 18 illustrates an example single-feed, two orthogonal PIFA structure with induced gaps according to at least one embodiment.

FIG. 19 illustrates an example single-feed, two orthogonal dipole structure with filters according to at least one embodiment.

FIG. 20 illustrates an example single-feed, two orthogonal slot structure with filters according to at least one embodiment.

FIG. 21 show a few examples of ergonomically suitable areas for placement of an SPMT antenna according to various embodiment.

FIG. 22 is a flow chart of a method of detecting a touch or gesture event according to at least one embodiment.

FIG. 23 is a block diagram of a wireless device with classification logic and a detection circuit according to one embodiment.

### DETAILED DESCRIPTION

Technologies directed to providing a single-port multi-touch (SPMT) antenna for realizing multiple touch buttons and directional swipe gestures are described. These technologies provide multi-touch and swipe gesture recognition in devices with wireless transceivers by using the SPMT antenna and multi-frequency monitoring techniques.

Touching a consumer device, such as smart speakers, earbuds, etc., in a certain way can be used as one type of user input as a user interface. A tap, double tap, long tap, swipe, etc., either touching or in close proximity, can be interpreted as user commands and set or modify the device settings according to a certain pre-agreed etiquette. Conventional consumer devices, such as earbuds and smart speaker devices, use buttons, accelerometers, or a dedicated “touch” integrated circuit (IC) to detect the touch by a user's finger. The touch IC often uses two or more “touch electrodes” and monitors the capacitance between different pairs as they are excited by the touch IC. The excitation is typically at a low frequency (e.g., 250 kHz), and it occurs in parallel to all other functions of the earbud. Touch detection with accelerometers suffers from “false positives” when vibrations in the environment, e.g., furniture on which a device is placed, accidentally trigger a response. Accelerometers typically require that the wireless device be “physically” touched. The consumer devices typically include an antenna system to wirelessly send or receive radio transmissions to and from another device.

In addition, users are demanding products with increasingly smaller form factors. The limited form factor can result in constraints on the physical volume and positioning of the touch electrodes (or physical buttons) and one or more antennas that are used to wirelessly send or receive radio transmissions to and from another device. The Bluetooth® wireless technology has been widely adopted across the consumer industry in many consumer products, including smart phones, smart wearable devices, wireless speakers, wireless earbuds, remote controls, etc. These devices often require a means to control the device, such as a touch sensing controller that enables a user to control operations of the device, such as playback, volume, power, or the like. To cater to the natural behavior of the user to touch the device, it is desirable to have a touch sensor at a specific location on the device. The demand for dedicated user-interactive features (such as touch-enabled features) uses real estate within these device. Antennas also use real estate within these devices. Some antennas are placed outside the device, such as on a cosmetic surface to improve the available real estate for antenna placement and design. However, this creates the need for additional manufacturing steps (e.g., such as polishing and painting) to mask the antenna pattern on the cosmetic surface (e.g., to match the color requirement) of the device. For conventional wireless devices with touch capability use two separate integrated circuits, one integrated circuit for antenna operations and another for touch sensing operations.

Aspects and embodiments of the present disclosure overcome these deficiencies and others by using an SPMT antenna for both radio frequency (RF) communications and as a sensor for touch sensing. In general, a sensor is a circuit that detects and converts a physical phenomenon like temperature, pressure, or the like into a resistance change, which is converted into a measurable voltage that can quantify the impact of the physical phenomenon. Aspects and embodiments of the present disclosure use the antennas as sensor technology by measuring reflected power in an RF path caused by an antenna impedance change from a presence of an object in proximity to the SPMT antenna. For example, a finger touch, a palm touch, or a palm hovering around the SPMT antenna can be detected and distinguished from one another and interpreted as user commands, such as pause or resume music, change a track, turn on a light, turn off a light, or the like. Touching a wireless device, such as a smart speaker or an earbud, in a certain way can be used as another user interface for interacting with the wireless device. Touch or hover events, such as a tap, a double tap, a long tap, a swipe, a tap and hold, a palm tap, a palm and hold, or the like, either touching or in close proximity to the SPMT antenna, can be interpreted as user commands. The user commands can set or modify the device settings according to specified configurations or operations. Aspects and embodiments of the present disclosure set forth apparatuses and methods for gesture detection by utilizing the existing radio transmissions of the wireless devices.

In addition to single touch or tap events or gestures, aspects and embodiments of the present disclosure can use a single SPMT antenna, a detection circuit, and classification logic to distinguish between multiple touch buttons and directional swipe gestures to provide more advanced touch and gesture detection in these devices. Aspects and embodiments of the present disclosure would not need multiple antennas and multiple detection circuits to detect the multiple touch points. Rather, the SPMT antenna can have a specific design, which when used with a multi-frequency monitoring methodology, enables distinguishing between touches at multiple distinct touch points or at a combination of touch points. This enables multi-touch recognition, directional gesture recognition, and multi-directional gesture recognition with a single SPMT antenna and a single detection circuit.

Aspects and embodiments of the present disclosure use the normal wireless transmissions of the wireless device and, instead of dedicated electrodes, uses the SPMT antenna as the sensing electrode. Aspects and embodiments of the present disclosure allow activation at some reasonable distance from the SPMT antenna (e.g., hovering up to 4-5 cm away from the device, depending on the device). Aspects and embodiments of the present disclosure can provide a better user experience than dedicated buttons and accelerometer-based designs.

Aspects and embodiments of the present disclosure can insert a simple detection circuit into an RF path, as the detection circuit is focused on detecting variations of the antenna impedance and not precise knowledge of the value of the antenna impedance. The classification logic can sample the antenna impedance at multiple frequencies and map these results to different touch points. Tracking the touches at multiple touch points over time can be used to determine swipe gestures (e.g., single-direction swipe gestures, multi-directional swipe gestures, or the like).

In at least one embodiment, a wireless device can include a processing device with an analog-to-digital converter (ADC) and classification logic and a detection circuit located in an RF path between a radio and an SPMT antenna. The SPMT antenna can be used to send or receive RF signals to or from the radio and radiate or receive electromagnetic energy to or from another wireless device. A first physical attribute of a first region of the SPMT antenna and a second physical attribute of a second region of the SPMT antenna affect an impedance of the SPMT antenna differently at a plurality of frequencies. The detection circuit is coupled between the radio and the SPMT antenna. The detection circuit can output an analog voltage signal to the ADC, the analog voltage signal representing the impedance of the SPMT antenna. The analog voltage signal can be based on (i.e., as a function of) an impedance value of the SPMT antenna. The ADC can sample the analog voltage signal at the plurality of frequencies over a period of time to obtain digital data. In particular, the ADC can sample the analog voltage signal at the plurality of frequencies at a first time to obtain first digital data and at a second time to obtain second digital data. The classification logic can use the digital data to classify one or more touch points caused by a presence of an object in proximity to the SPMT antenna over the period of time as a touch event or a gesture event. In particular, the classification logic can determine, using the first digital data, that a presence of an object in proximity to the SPMT antenna is located at a first position corresponding to the first region of the SPMT antenna. The classification logic can determine, using the second digital data, that the presence of the object in proximity to the SPMT antenna is located at a second position corresponding to the second region of the SPMT antenna. The classification logic can determine a gesture event using the first position and the second position. The processing device can perform an action in response to the touch event or gesture event.

In at least one embodiment, a wireless device can include a processing device with an analog-to-digital converter (ADC) and classification logic and a detection circuit located in an RF path between a radio and an SPMT antenna. A first physical attribute of a first region of the SPMT antenna and a second physical attribute of a second region of the SPMT antenna affect an impedance of the SPMT antenna differently at a plurality of frequencies. The processing device can sample the analog voltage signal at a plurality of frequencies over a period of time to obtain digital data. The classification logic can use the digital data to classify one or more touch points caused by a presence of an object in proximity to the SPMT antenna over the period of time as a touch event or a gesture event. The processing device can perform an action in response to the touch event or gesture event.

As described in more detail below, the antenna design of the SPMT antenna and multi-frequency monitoring enable the ability to detect and distinguish between multiple touch points, directional swipe gestures, and multi-directional swipe gestures.

The antenna design of the SPMT antenna aims to create some distinct touch points on and around the SPMT antenna that touching at those said points affects the antenna impedance differently and uniquely at different frequencies. The antenna design of the SPMT antenna can be achieved in different ways, including dipole or combination of dipoles with asymmetries in physical attributes (e.g., size, shape, layer layout, materials), multi-modal antenna designs, planar inverted F antenna (PIFA) structures with induced gaps, slot antenna designs, or the like. Examples of different antenna designs are described in more detail below.

The multi-frequency monitoring uses sampling of the output voltage signal from a detector circuit (e.g., an impedance detector circuit) at multiple frequencies. The multi-frequency monitoring at multiple frequencies enables the different touch points mentioned above to be uniquely classified or identified. When a swipe gestures is performed, it is recognized by tracking the output voltage variation at said frequency points along the trajectory from one touch point to another over a period of time. With the proper antenna design mentioned above, the voltage variations at different frequencies provide unique signatures for different touch points. In at least one embodiment, the classification can implement a dedicated classification algorithm (e.g., pre-loaded in a System on Chip (SoC)) that classifies the touch/swipe events and maps them to different actions/commands for the device according to a pre-agreed etiquette. Additional details of the antenna design and multi-frequency monitoring are described below.

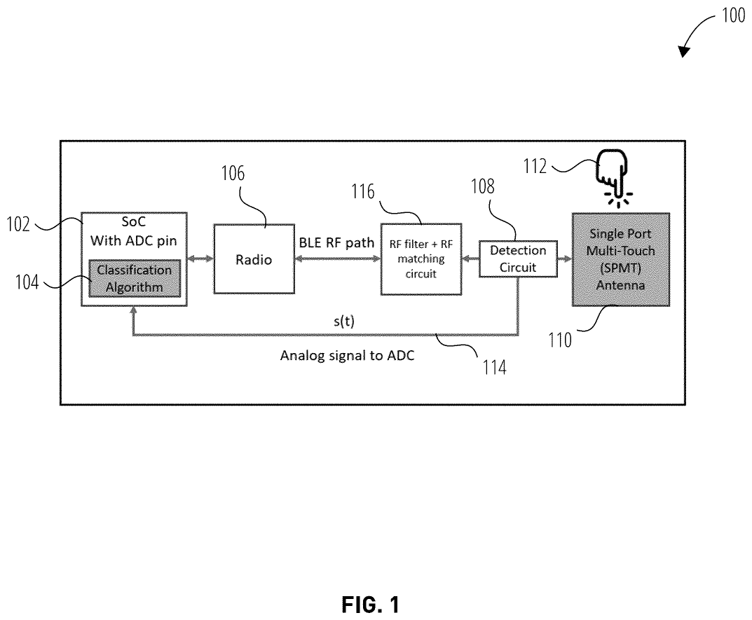

FIG. 1 is a block diagram of a wireless device 100 with an SPMT antenna 110, classification logic 104 (labeled classification algorithm), and detection circuit 108 to detect touches at multiple touch points for a touch event or a gesture event caused by an object 112 in proximity to the SPMT antenna 110 according to at least one embodiment. The wireless device 100 includes a processing device 102 that includes an analog-to-digital converter (ADC) and classification logic 104. In at least one embodiment, the processing device 102 is a SoC that manages, among other things, the wireless protocol of a radio 106 coupled to the processing device 102 and other aspects of the behavior and operation of the wireless device 100. The processing device 102 can control operations of the radio 106 to communicate with one or more devices over one or more communication links. The radio 106 can implement the Wi-Fi® technology, the Bluetooth® technology, or both. Alternatively, the radio 106 can implement other radio technologies. The processing device 102 is coupled to the detection circuit 108, which is coupled between the radio 106 and the SPMT antenna 110.

As described in more herein, the SPMT antenna 110 can have different physical attributes at different regions of the SPMT antenna 110. The different physical attributes affect the impedance of the SPMT antenna 110 differently at different frequencies. The characteristics of the SPMT antenna 110 change when an user performs a gesture such as tap/touch/swipe/hover in close proximity to the SPMT antenna 110. Any such gesture is a time varying event. The detection circuit 108, which is inserted in the RF path, can translate the antenna's instantaneous characteristics into a time varying output signal 114, defined as s(t), which is guided to, and read by the classification logic 104. As described herein, a gesture detection method relies on variations of the antenna impedance (i.e. differences between being touched and not being touched). The detection method can apply regardless of the variability from user to user, or variability from device to device. The level of the output signal 114, s(t), from the detection circuit 108 can be adjusted by the appropriate choice of its constituent components. The present embodiments are focused on enabling the functionality of multiple touch buttons simultaneously, as well as complicated gestures detection, such as directional swipes, with a single antenna.

The detection circuit 108 can measure an amount of reflection signals, in an RF path between the radio 106 and the SPMT antenna 110, caused by changes in the impedance of the SPMT antenna 110. The detection circuit 108 can provide an output signal 114, s(t), to the processing device 102. The output signal 114 can be an analog voltage output signal (also referred to herein as voltage waveform, analog voltage signal, or the like) that represents the amount of reflection signals. The changes in impedance can be caused by the presence of an object 112 in proximity to the SPMT antenna 110. The wireless device 100 can include an ADC channel that can sample the output signal 114. The ADC can sample the output signal 114 at the multiple frequencies for the classification logic 104. The classification logic 104 can use the samples to determine a presence of an object in proximity to the SPMT antenna 110, as well as touch, hover, or gesture events, corresponding to one or more touches or gestures that cause the wireless device 100 to perform one or more actions.

In at least one embodiment, the detection circuit 108 is inserted just in front of the SPMT antenna 110 in an RF path between the radio 106 and he SPMT antenna 110. The detection circuit 108 can provide the analog voltage output signal 114, s(t), which is guided to, and read by the processing device 102 via one of its embedded ADC channels. The characteristics of the SPMT antenna 110 change when it is approached by an object, such as a finger or palm of a user. Concomitantly, the output signal 114 of the detection circuit 108 changes. The classification logic 104 in the processing device 102 monitors the temporal changes in the output signal 114, s(t), and interprets the temporal changes as user commands based on a pre-determined etiquette. In at least one embodiment, the RF path also includes RF filtering and matching circuitry 116 coupled between the radio 106 and the detection circuit 108. The RF filtering and matching circuitry 116 can perform RF filtering of the RF signals and provide impedance matching between the radio 106 and the SPMT antenna 110. The presence of the detection circuit 108 in the RF path does not significantly impact the radio operations of the radio 106.

In at least one embodiment, the wireless device 100 is a smart speaker device (e.g., the Amazon Echo device). The smart speaker device can be configured to wirelessly communicate radio signals to and from another device. The smart speaker device includes a housing and a circuit board that is disposed within the housing. The SPMT antenna can be printed or disposed on a non-cosmetic surface (e.g., the top inside surface of the housing). This decreases the cost of the smart speaker device by shifting the design to the non-cosmetic surface of the housing, thereby eliminating the need for secondary manufacturing processes. The SPMT antenna can be printed or disposed on a cosmetic surface as well. Instead of including separate touch circuitry coupled to the SPMT antenna 110, the detection circuit 108 is coupled between the radio 106 and the SPMT antenna 110. In other embodiments, the SPMT antenna 110 can be deployed as a substitute for any mechanical or electrical button used in a device. For example, the SPMT antenna 110 can be used to turn lights on and off, turn a device on and off, change a state of the device based on the user interaction, or the like.

In at least one embodiment, the wireless device 100 is a wireless earbud (or simply an earbud). The wireless earbud can be configured to wirelessly communicate radio signals to and from an audio source for processing and playback by one or more speaker components of the wireless earbud. The wireless earbud includes a housing and a circuit board that is disposed within the housing. The SPMT antenna architecture of the wireless earbud can be printed or disposed on a non-cosmetic surface (e.g., the top inside surface of the housing) of the wireless earbud. At least some portion of a metal element serves effectively as a zero-footprint antenna. A zero-footprint antenna means there is no dedicated ground clearance on the circuit board dedicated to the antenna. This enables a highly miniaturized product. Instead of including separate touch circuitry coupled to the SPMT antenna 110, the detection circuit 108 is coupled between the radio 106 and the SPMT antenna 110. The wireless earbud can include an audio output device, such as an audio speaker, to produce/playback audio, such as voice calls, media, etc. In other embodiments, the SPMT antenna 110, the classification logic 104, and the detection circuit 108 can be deployed as a substitute for any mechanical or electrical button used in a device to turn lights on and off, turn a device on and off, change a state of the device based on the user interaction, or the like.

In at least one embodiment, the radio 106 is disposed on the circuit board and is coupled to an antenna feed (RF input or RF feed point). The radio 106 can drive the SPMT antenna 110 using one or more RF signals in an RF path. A current flow on the RF path can induce current on the SPMT antenna 110 to cause the SPMT antenna 110 to radiate electromagnetic energy. The radio 106 can also receive RF signals, received as electromagnetic energy by the SPMT antenna 110. The SPMT antenna 110 can be a monopole, a loop, a patch, a slot, or the like. The radio 106 can cause the SPMT antenna 110 to radiate and receive electromagnetic energy in a specified frequency range, such as the 2.4 GHz frequency band for wireless personal area network (WPAN) applications (e.g., Bluetooth® Classic or Bluetooth® Low Energy (BLE) technology), wireless local area network (WLAN) applications (e.g., Wi-Fi® technology), or the like. In one embodiment, an operating frequency of the radio 106 is a wide area network (WAN) frequency band (e.g., 5G, Long Term Evolution (LTE) technology, or the like).

In at least one embodiment, during the operation of the wireless device 100, the radio sends an RF signal to the SPMT antenna 110 via a first path (primary RF path) to radiate electromagnetic energy. The detection circuit 108 is located in a second path (also referred to herein as a shunt load, a trapped path, or a coupled path). The detection circuit 108 can detect and convert an amount of reflected power in the first path to a voltage waveform. The amount of reflected power is also referred to as “coupled power.” The amount of reflected power in the first path varies in response to changes in impedance of the SPMT antenna 110. The ADC of the processing device 102 can convert the voltage waveform into digital data. The classification logic 104 uses the digital data to detect a change in impedance that satisfies a criterion representing a touch event or a hover event caused by a presence of an object 112 in proximity to the SPMT antenna 110. The classification logic 104 can also use the digital data, sampled at multiple frequencies, to classify multiple touches over a period of time as a gesture event (or a touch event). The gesture event can be a directional swipe gesture, a multi-directional swipe gesture, or the like.

In at least one embodiment, the processing device 102 can perform an action in response to the touch event or the hover event. In at least one embodiment, the action is at least one of starting an audio file, stopping an audio file, pausing playback of the audio file, resuming playback of the audio file, changing playback of a subsequent audio file in a list or a previous audio file in the list, increasing a volume, or decreasing the volume.

In at least one embodiment, the classification logic 104 is firmware executed by the processing device 102. The firmware can use the ADC readings to detect different use cases described herein. In at least one embodiment, the classification logic 104 is a hardware, such as a state machine of the processing device 102. In at least one embodiment, the classification logic 104 is combination logic. In at least one embodiment, the classification logic 104 is a detection algorithm. The detection algorithm can be implemented using processing logic comprising hardware, software, firmware, or any combination thereof.

In at least one embodiment, the classification logic 104 establishes, at a first time, a baseline representing that the object 112 is not present or interacting with the wireless device 100. The classification logic 104 can establish baseline values at each of the frequencies. At a second time, the classification logic 104 determines that the change in impedance exceeds the baseline by a threshold amount. The classification logic 104 can compare a drift in magnitude and polarity of the sampled signals from the baseline value at each of the frequencies. The threshold amounts above or below the baseline can be the criterion. The criterion can be specified for a tap, a double tap, a palm tap, a palm tap and hold, a swipe, a tap and hold, a single-direction gesture, a multi-directional gesture, or the like. The criterion can also be based on the expected signatures at the different frequencies. The signatures can be mapped to different touch points on the device. In at least one embodiment, the classification logic 104 can classify the one or more touch points as the touch event or the gesture event by comparing a drift in magnitude and polarity of the sampled analog voltage signal from a baseline value at each of a set of frequencies. The classification logic 104 can determine a set of one or more touches at one or more of a set of touch points from comparisons of the drift from the baseline value. The classification logic 104 can determine a type of event, comprising the touch event or the gesture event, from an order of occurrence for the set of one or more touches.

In at least one embodiment, the classification logic 104, to classify the one or more touch points as the touch event or the gesture event, determines a first position of the object at a first time responsive to the analog voltage signal having a first value at a first frequency of the plurality of frequencies and a second value at a second frequency of the plurality of frequencies. The classification logic 104 determines a second position of the object at a second time responsive to the analog voltage signal having a third value at the first frequency and a fourth value at the second frequency.

In at least one embodiment, the SPMT antenna 110 of the radio 106 is made to communicate with other radios at relatively far distances. So, they are typically placed at such a location on a device so that they can radiate efficiently and be manufacturable at an appropriate cost. The SPMT antenna 110 can also be placed at a location so as to also provide an ergonomically convenient user interface for the purpose of gesture detection. In some embodiments, if only simple gestures, such as touch or mere proximity (e.g., hovering over), are sought, any existing antenna could work, with minimal modifications, if any, provided the SPMT antenna 110 is placed at the desired location for the detection of the touch/hover events. In other embodiments, specific antenna designs can enable more complicated gestures, such as swipes. Yet, other antenna designs enable the detection of gestures at several, distinguishable points.

In at least one embodiment, the wireless device 100 can detect changes in impedance to detect a touch event, a hover event, or a gesture event, caused by a object 112 (e.g., object) in proximity to the SPMT antenna 110. The wireless device 100 can include RF front-end circuitry, including the RF filtering and matching circuitry 116 and the detection circuit 108. The detection circuit 108 can measure an amount of reflection signals in the RF front-end circuitry. The variations in reflection signals can be caused by changes in the impedance of the SPMT antenna 110. The detection circuit 108 can provide an analog signal (output signal 114) to the processing device 102. The analog signal can be an analog voltage output signal that represents the amount of reflection signals. The changes in impedance can be caused by the presence of an object in proximity to the SPMT antenna 110. The processing device 102 can include an ADC that can sample the analog signal to obtain digital data or samples of amplitude or gain values of the analog signal at a specified frequency. The processing device 102 can sample the analog signal at multiple frequencies for classification by the classification logic 104. The classification logic 104 can use the samples to determine a presence of an object in proximity to the SPMT antenna 110, as well as touch or hover events, corresponding to one or more gestures that cause the wireless device 100 to perform one or more actions.

In at least one embodiment, the processing device 102 cause the radio 106 to send, at a first time, a first RF signal to the SPMT antenna 110 to radiate electromagnetic energy at a first frequency. At the first time, the processing device 102 can measure a first voltage based on a first impedance value of the SPMT antenna 414 using the detection circuit 108 and the first RF signal. At a second time, the processing device 102 cause the radio 106 to send a second RF signal to the SPMT antenna 110 to radiate electromagnetic energy at a second frequency. At the second time, the processing device 102 measures a second voltage based on a second impedance value of the SPMT antenna 110 using the detection circuit 108 and the second RF signal. The processing device 102 can determine, using at least the first voltage and the second voltage, a change in impedance that satisfies a criterion representing a touch event or a hover event caused by an object in proximity to the SPMT antenna 110. The processing device 102 performs an action in response to the touch event or the hover event. The action can be any one of the following actions: starting an audio file; stopping an audio file; pausing playback of the audio file; resuming playback of the audio file; changing playback of a subsequent audio file in a list or a previous audio file in the list; increasing a volume; decreasing the volume, or the like. In at least one embodiment, the touch event is at least one of a tap, a double tap, a tap and hold, a swipe, a palm tap and hold, or the like. In other embodiments, some or all of these operations are performed by the classification logic 104.

In at least one embodiment, the processing device 102 cause the radio 106 to send, at a first time, a first RF signal to the SPMT antenna 110 to radiate electromagnetic energy at a first frequency. At the first time, the processing device 102 can measure a first voltage based on a first impedance value of the SPMT antenna 414 using the detection circuit 108 and the first RF signal. The processing device 102 can sample the first voltage at a set of frequencies. At a second time, the processing device 102 cause the radio 106 to send a second RF signal to the SPMT antenna 110 to radiate electromagnetic energy at a second frequency. At the second time, the processing device 102 measures a second voltage based on a second impedance value of the SPMT antenna 110 using the detection circuit 108 and the second RF signal. The processing device 102 can sample the second voltage at the set of frequencies. The processing device 102 can determine a touch point from the sampled first voltage and a second touch point from the sampled second voltage. The processing device can determine, from the first and second touch points, a touch event or a gesture event caused by an object in proximity to the SPMT antenna 110. The processing device 102 performs an action in response to the touch event or the gesture event. The action can be any one of the following actions: starting an audio file; stopping an audio file; pausing playback of the audio file; resuming playback of the audio file; changing playback of a subsequent audio file in a list or a previous audio file in the list; increasing a volume; decreasing the volume, or the like. In at least one embodiment, the touch event is at least one of a tap, a double tap, a tap and hold, a swipe, a palm tap and hold, or the like. In other embodiments, some or all of these operations are performed by the classification logic 104.

In at least one embodiment, the radio 106 sends the first RF signal in an advertising channel of a wireless personal area network (WPAN) protocol. In at least one embodiment, the first RF signal is included in an advertising channel of the Bluetooth Low Energy (BLE) standard. In at least one embodiment, the radio 106 sends the first RF signal in a first advertising channel of the WPAN protocol and the second RF signal in a second advertising channel of the WPAN protocol. In at least one embodiment, the first RF signal is included in a first advertising channel of the BLE standard, and the second RF signal is included in a second advertising channel of the BLE standard. It should be noted that technologies described herein could be applied to many transmitting radios. A BLE radio is a low-cost solution amongst the typical radios deployed in wireless devices. It should also be noted that the technologies described herein are directed to touch and gesture recognition while transmitting data on the SPMT antenna 110. In some cases, different features could be used to accommodate touch and gesture recognition while receiving data on the SPMT antenna 110.

In at least one embodiment, the detection circuit 108 measures the first voltage by detecting an amount of reflection coefficient of the SPMT antenna 110 (i.e., reflected power in the first path). The detection circuit 108 can convert the amount of reflected power to a voltage waveform. The amount of reflected power in the first path varies in response to changes in impedance of the SPMT antenna 110. The processing device 102 can convert, using the ADC, the voltage waveform into digital data. In at least one embodiment, the detection circuit 108 measures the first voltage by detecting an amount of reflection coefficient of the SPMT antenna 110 coupled to a radio in a first path using a detection circuit 108. The detection circuit 108 generates, using the amount of reflection coefficient, the voltage waveform. The amount of reflection coefficient varies in response to changes in impedance of the SPMT antenna 110. Although various embodiments described herein are directed to a single object being detected, in other embodiments, the SPMT antenna 110, the classification logic 104, and the detection circuit 108 can detect and classify multiple objects concurrently or simultaneously, such as multi-finger touches or sequence of touches. These can be used for more advance gestures. That is simultaneous touches can have different signal signatures, permitting more complex gestures. These touches can be simultaneous touches, concurrent touches, or sequential touches in a predetermined order. Also, the event of touching two or more points simultaneously (e.g., touching with two fingers) can have a unique signature and, therefore, can be distinguishable from other touch events, and is itself a legitimate touch event.

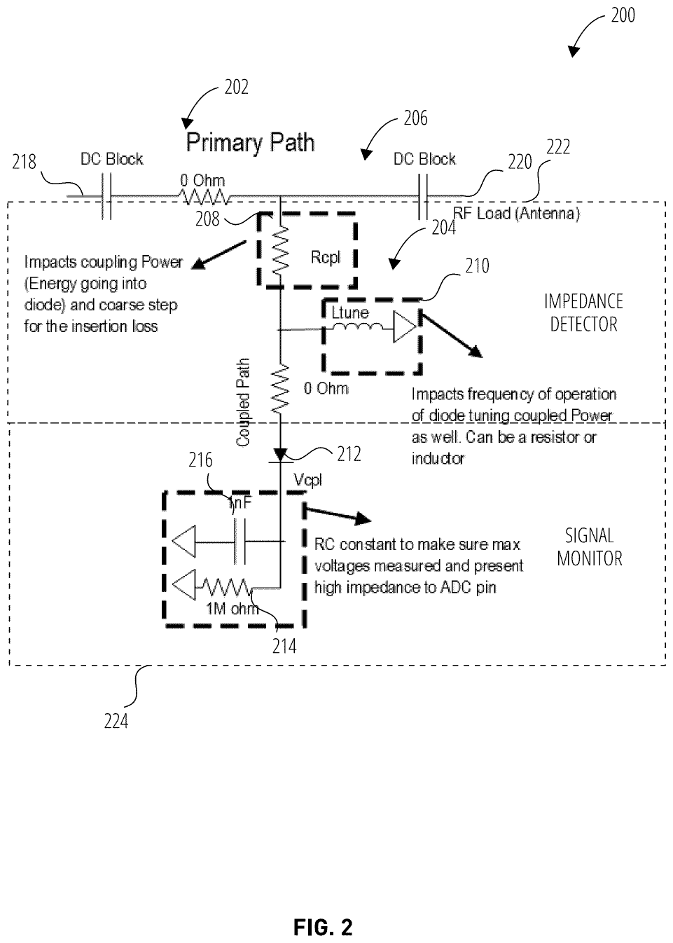

In at least one embodiment, the detection circuit 108 can include a resistive-coupled circuit to detect an impedance of the SPMT antenna 110, such as described in more detail below with respect to FIG. 2.

In at least one embodiment, the detection circuit 108 includes the components of the detection circuit 200. Alternatively, other detection circuits can be used to translate the antenna's instantaneous characteristics into the time varying output signal 114, defined as s(t).

FIG. 2 is a schematic diagram of a detection circuit 200 that detects and converts an amount of reflected power in an RF path 202 (also referred to as primary path or first path) to a voltage waveform according to at least one embodiment. The RF path 202 is between an RF input 218 and an RF load 220 (SPMT antenna 110). The RF path 202 can include direct current (DC) blocks and an optional resistor. The optional resistor is illustrated as zero ohms, but the resistor can have other resistances based on design considerations. As described herein, the amount of reflected power in the RF path 202 varies in response to changes in impedance of an RF load 220 (SPMT antenna 110). In at least one embodiment, the detection circuit 200 includes a shunt load in front of the RF load 220 (SPMT antenna 110) and an envelope detection diode circuit.

In at least one embodiment, the detection circuit 200 includes an impedance detector 222 and a signal monitor 224. The impedance detector 222 is a circuit placed in front of the SPMT antenna 110 in a shunt path (parallel path) to the RF path 202. As illustrated in the embodiment of FIG. 2, the impedance detector 222 includes (i) a first resistor 208 (Rcpl) that regulates an amount of power coupled in a “coupled path” 204, and (ii) an inductor 210 (Ltune) (or a third resistor (Rtune)) that adjusts an output of the signal monitor 224 in a specified frequency band. The first resistor 208 can impact a “coupled power” (i.e., energy going into signal monitor 224) and coarse step for the insertion loss. The inductor 210 (or third resistor) can impact the frequency of operation of the signal monitor 224 by tuning the coupled power as well. The signal monitor 224 is a circuit that can monitor a signal generated by the impedance detector 222. As illustrated in the embodiment of FIG. 2, the signal monitor 224 is an envelope detector diode and accompanying capacitor and resistor elements.

The impedance detector 222 can present a suitably low Insertion Loss (i.e. it draws little power away from the transmitted power). For example, the first resistor 208 can have a large resistance, such as Rcpl=300 Ohms, to present a low insertion loss in the RF path 202. The impedance detector 222 can contain circuit elements in an architecture or topology such that the signal across one or more elements is some function of the impedance of the SPMT antenna 110, Zant. For example, a balanced Wheatstone bridge or other circuits can provide a voltage signal across a resistor in the circuit, which is directly proportional to a commonly used quantity, the SPMT antenna Reflection Coefficient, S11=(Zant−Zo)/(Zant+Zo), where Zo is some fixed reference impedance, typically 50 Ohms. Zant and, consequently, S11 (Reflection Coefficient), change when an object approaches the antenna. However, the proportionality constant is fixed, for all frequencies, regardless of the antenna and its variations. The embodiment shown in the disclosure is simpler than the Wheatstone bridge (lower cost) but it gives us a voltage signal across the Ltune which is not as neatly proportional to Zant, or S11.

In other embodiments, the impedance detector 222 can present two or more signals of interest to be monitored and/or compared via multiple signal monitor circuits (e.g. phase detectors).

An ideal signal monitor would not change the signal it monitors. But realistic circuits do. Such is, for example, the case with the envelop detector circuit of FIG. 2. With the diode parasitics in mind, the choice of the inductor 210 (Ltune) has been made to ensure enough power going into the diode detector. This can ensure good sensitivity in monitoring changes of the voltage signal across the inductor 210 (Ltune). For the diode to perform as an envelop detector, the value of the inductor 210 (Ltune) can be selected so that the voltage across it is low enough so as not to be “clipped” by the diode. The description above describes the physical characteristics of the impedance detector 222 and the signal monitor 224. In other embodiments, other circuits can be used to detect a change in the impedance of the antenna for detecting a presence of an object in proximity to the antenna.

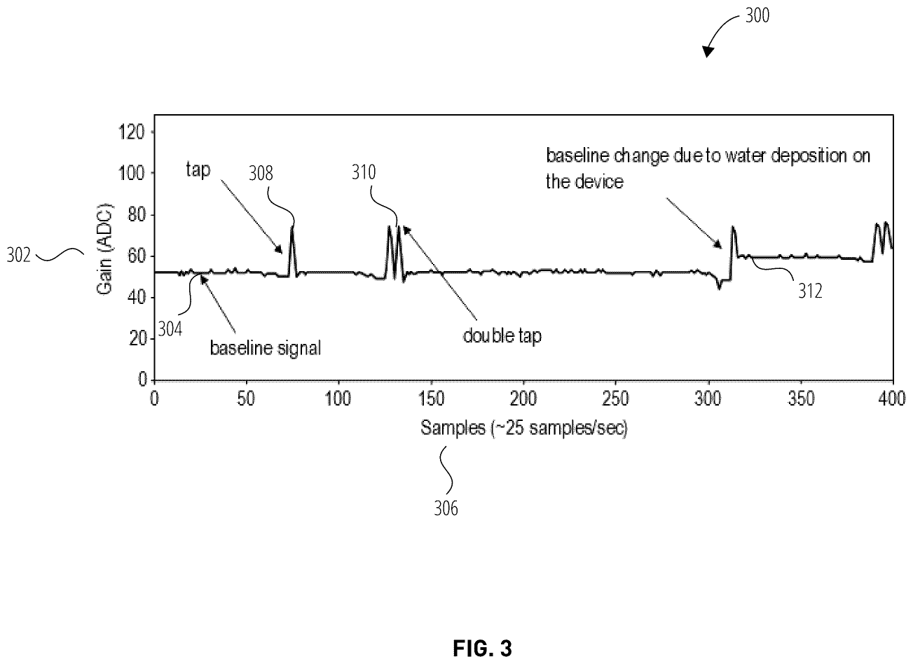

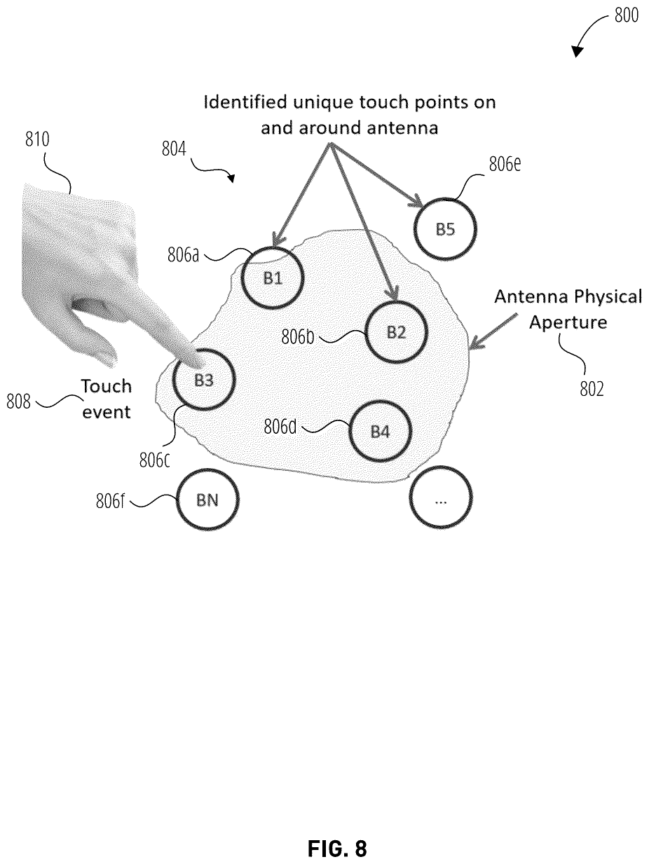

On the RF path 202 (also referred to as the primary path), the voltage can include an “incident” and a “reflected” wave component. When the radio transmits a signal, the incident wave travels toward the SPMT antenna 110. The reflected wave is reflected by the antenna and travels back towards the radio. The reflected-to-incident wave ratio is the aforementioned S11 quantity (Reflection Coefficient). When there is no reflected wave from the antenna, S11=0, and the signal monitored by the envelope detector circuit of a Wheatstone bridge detector will be zero. However, using the impedance detector 222 of FIG. 2, the monitored signal will have a non-zero value even if S11=0 (i.e. even if there is no reflected wave). In at least one embodiment, as illustrated in FIG. 2, the detection circuit 200 is a resistive-coupled circuit with a Schottky diode 212. The resistive-coupled circuit includes an unequal resistor divider 206 with (i) a first resistor 208 that regulates an amount of power coupled in a “coupled path” 204 (also referred to as second path or tapped path) and an insertion loss in the RF path 202. The first resistor 208 can impact a “coupled power” (i.e., energy going into Schottky diode 212) and coarse step for the insertion loss. The resistive-coupled circuit includes (ii) an inductor 210 (or a third resistor, or a combination thereof) that adjusts an output of the Schottky diode 212 (also referred to as a Schottky envelope detector diode) in a specified frequency band. The inductor 210 (or third resistor) can impact the frequency of operation of the Schottky diode 212 by tuning the coupled power as well. The Schottky diode 212 can convert an alternative current (AC) signal into a pulsating direct current (DC) signal. The resistive-coupled circuit includes a second resistor 214 and a capacitor 216, each coupled to the Schottky diode 212 and coupled in parallel to one another. The pulsating DC signal charges the capacitor 216 during positive half-cycles and discharges through the second resistor 214 during gaps between the half-cycles to obtain the envelope of the voltage waveform. The second resistor 214 and capacitor 216 provide an RC constant to make sure an accurate envelope of the voltage waveform is measured and present a high impedance to an ADC channel (i.e., ADC pin) of a processing device coupled to the output (Vcpl) of the Schottky diode 212. The ADC of the processing device can convert the voltage waveform into digital data to detect a change in impedance that satisfies a criterion representing a touch event or a hover event caused by a presence of an object in proximity to the RF load 220 (SPMT antenna 110). The processing device can perform an action in response to the touch event or the hover event. It should be noted that there are other conventional circuits that can detect and measure an absolute impedance of an antenna. The embodiments described herein rely on variations of the antenna impedance for gesture detection. The embodiments described herein can be used in various devices in spite of the variability from user to user or device to device. The detection circuit 200 can output an output signal, s(t), to the processing device for processing by the classification logic 104. The level of the output signal, s(t), from the detection circuit 200, can be adjusted by the appropriate choice of its constituent components. FIG. 2 illustrates one embodiment of the detection circuit. Alternatively, other detection circuits can be used. Additional details of the classification logic (i.e., detection algorithm) are described below with respect to FIG. 3 to FIG. 22. In particular, FIG. 3 to FIG. 7 describe how the classification logic 104 can detect single touch or tap type events for simple single-touch gestures. FIG. 8 to FIG. 22 describe how the classification logic 104 can classify multiple touches over time for touch events or gesture events.

FIG. 3 is a graph 300 illustrating an output signal of a detection circuit during normal communication transmissions of a radio according to at least one embodiment. As described herein, the output signal can be sampled by the ADC during transmissions to produce samples 306. Each sample has a corresponding gain value 302 (also referred to as an amplitude value) measured by the detection circuit. The temporal behavior of the output signal can be used by the classification logic to establish a baseline 304 (also referred to as a baseline signal). Then monitored variations from the baseline 304 can be mapped onto suitable user gestures and interpreted as intentional user commands to alter a state and/or operation of the device. For example, as illustrated in FIG. 3, a single tap 308 on the device can result in a change in gain values 302 above the baseline 304 as a single spike. The single spike can exceed the baseline 304 by a threshold amount. For example, a single tap on an earbud during audio streaming could be detected as the tap 308 and enable a “skip track” function, a play function, a pause function, or the like. Other gestures and actions are possible. For example, a wave of the hand in the proximity of the SPMT antenna 110 on a smart speaker device during music play could enable a “skip track” function, a play function, a pause function, or the like.

For another example, as illustrated in FIG. 3, a double tap 310 on the device can result in a change in gain values 302 above the baseline as two spikes within a specified amount of time. For example, a double tap on an earbud during audio streaming could be detected as the double tap 310 and enable a “skip track” function, a play function, a pause function, or the like.

As described herein, since the classification logic 104 relies on variations of the antenna impedance for gesture detection (instead of absolute impedance), the baseline 304 can change due to environmental or wearing conditions. For example, as illustrated in FIG. 3, the baseline 304 can experience a baseline change 312 to a higher level due to liquid deposition on the device. It should be noted that the SPMT antenna placement and sensitivity of the detection circuit can be adjusted to adjust a distance of an object can be reliably detected.

In at least one embodiment, the output signal, s(t), is sampled during normal communication transmissions of the radio. Depending on the radio, certain transmissions may be easier to handle for the purpose of gesture detection. For example, for Bluetooth Low Energy (BLE) radios, the classification logic samples the output signal, s(t), using the ADC during the advertising transmissions at one or more of the three advertising channels (i.e., 2402, 2426, and 2480 MHz).

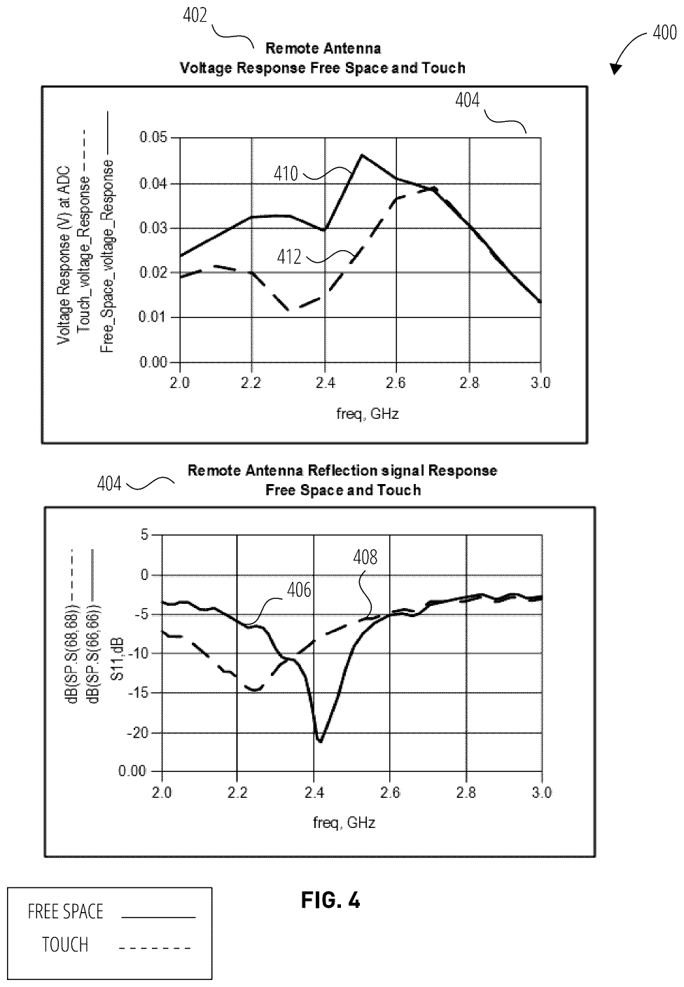

As described herein, a detection circuit is used to convert the reflected power to voltage, and this change in voltage level is used by a detection algorithm (classification logic) to map to different use cases described herein. The detection circuit can be a low-cost detection circuit. The detection circuit can be various types of topologies, including a resistive-coupled topology with a Schottky envelope detector diode. This technology can use an existing ADC in the processing device (or SoC). The detection circuit can be used in other devices with remote antennas, ring doorbell antennas with external ADCs, or the like. A basic block diagram of an SPMT antenna as a sensor is shown and described above with respect to FIG. 1. The impedance change that causes changes in reflected power as captured in a voltage waveform is shown and described below with respect to FIG. 4.

FIG. 4 illustrates graphs 400 of a voltage response 402 in free space and in the presence of an object using a remote SPMT antenna and a graph of a reflection signal response 404 in free space in the presence of an object using the remote SPMT antenna according to at least one embodiment. In this embodiment, a remote control device has a pigtail SPMT antenna coupled to a detection circuit inside the remote control device. When an object is not in proximity to the remote control device, a free space reflection signal response 406 is detected at the detection circuit. When the object is in proximity to or touching the remote control device, a touch reflection signal response 408 is detected at the detection circuit. The free space reflection signal response 406 and touch reflection signal response 408 can be the reflection coefficient in decibels (dBs). The change between the free space reflection signal response 406 and touch reflection signal response 408 shows the impact caused by a touch event on the remote control device. As illustrated in the free space reflection signal response 406 and touch reflection signal response 408 can be differentiated over a frequency range of approximately 2.3 GHz to 2.6 GHz.

Similarly, when an object is not in proximity to the remote control device, a free space voltage response 410 is measured at the ADC. When the object is in proximity to or touching the remote control device, a touch voltage response 412 is measured at the ADC. As illustrated in the free space voltage response 410 and touch voltage response 412 can be differentiated over a frequency range of approximately 2.0 GHz to 2.7 GHZ.

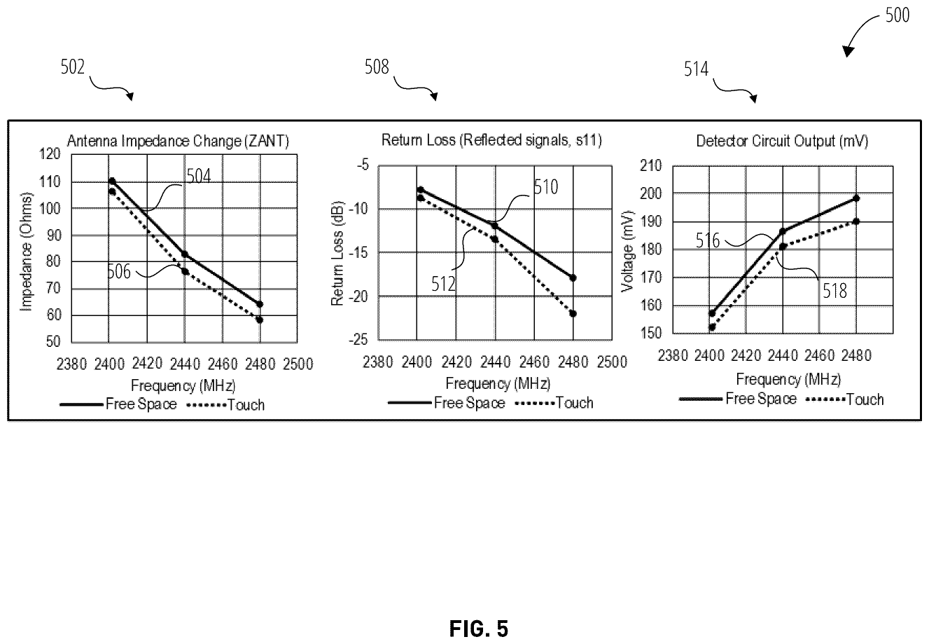

As described above, there can be a tradeoff between the insertion loss and coupled power. The amount of coupled power and, consequently, of the detection voltage depends on the antenna impedance (Zant) and varies with the variations of Zant, as shown and described below with respect to FIG. 5.

FIG. 5 illustrates graphs 500 of antenna impedance change, return loss, and detector circuit output signals according to at least one embodiment. FIG. 5 shows the change in the antenna impedance due to the touch impacting the reflected power in the RF Path, which is detected at the detector output. A first graph 502 illustrates an antenna impedance magnitude change 504 (Zant) in free space versus an antenna impedance magnitude change 506 with a presence of an object. A second graph 508 illustrates a return loss 510 in free space versus a return loss 512 with a presence of an object. A third graph 514 illustrates a detector circuit output 516 in free space versus a detector circuit output 518 with a presence of an object. There can be some dependencies on the ADC. For example, the number of ADC steps and the step size determine what which gestures can be detected and differentiated.

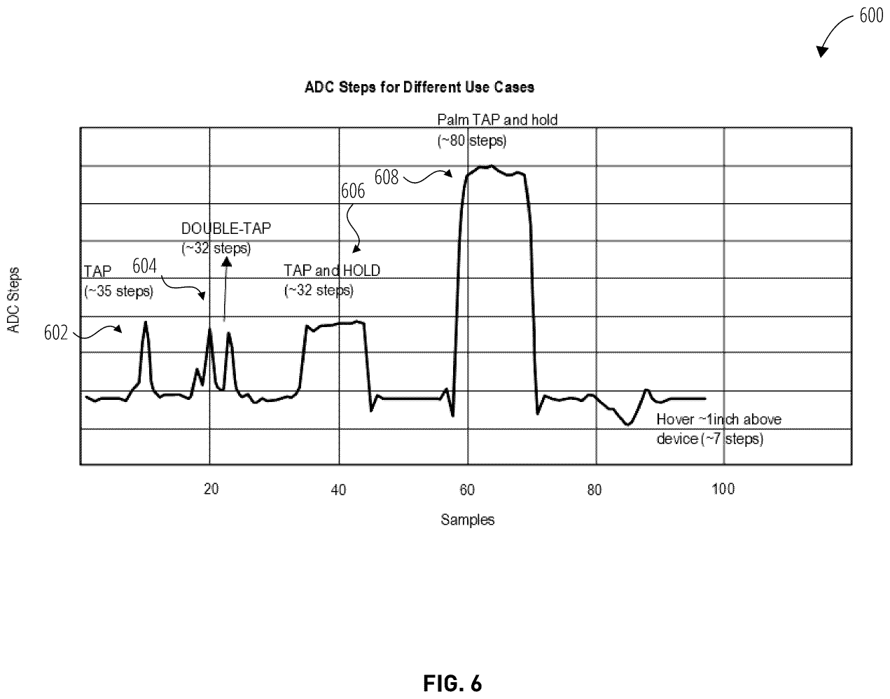

FIG. 6 is a graph 600 showing ADC steps for different use cases according to at least one embodiment. Graph 600 includes ADC steps corresponding to a tap 602, a double tap 604, a tap and hold 606, and a palm tap and hold 608. The tap 602 is a single spike in the ADC steps. The double tap 604 has two spikes within a specified amount of time. The tap and hold 606 has a rising edge, a first level of ADC steps for a specified amount of time, and a falling edge. The palm tap and hold 608 has a rising edge, a second level of ADC steps for a specified amount of time, and a falling edge. The second level is higher than the first level.

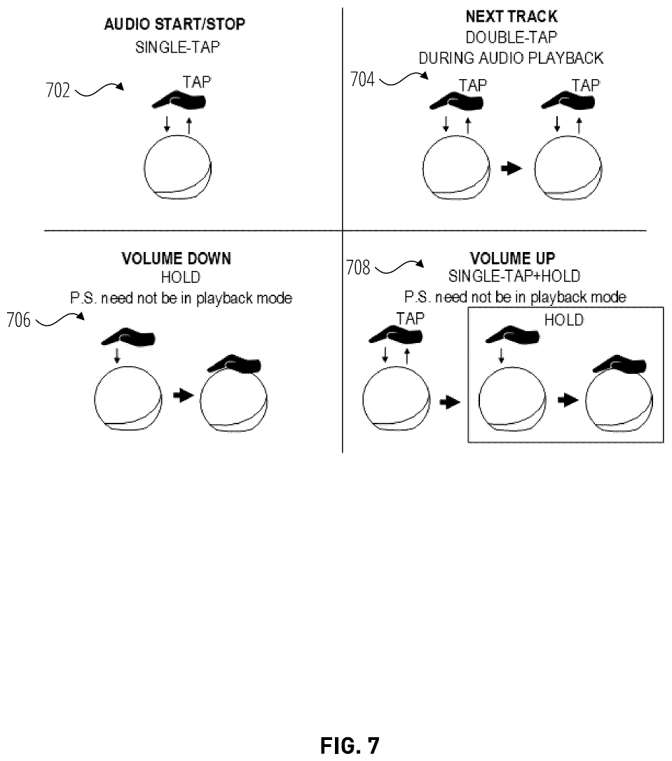

FIG. 7 illustrates multiple gestures and corresponding actions according to at least one embodiment. A single tap gesture 702 involves a user momentarily placing their hand over a device and removing their hand within a specified amount of time. As a result of detecting the single tap gesture 702, the device can start or stop audio playback during an audio playback mode. A double-tap gesture 704 involves the user momentarily placing their hand over a device, removing their hand within a specified amount of time, momentarily placing their hand over the device again within a specified amount of time, and removing their hand within a specified amount of time. As a result of detecting the double-tap gesture 704, the device can skip to a next track during an audio playback mode. A hold gesture 706 involves a user placing their hand over a device and keeping their hand there for a specified amount of time. As a result of detecting the hold gesture 706, the device can decrease the volume. The volume can be decreased in the playback mode or in other modes. A tap and hold gesture 708 involves a user momentarily placing their hand over a device and removing their hand within a specified amount of time, placing their hand again over the device and keeping their hand there for a specified amount of time. As a result of detecting the tap and hold gesture 708, the device can increase the volume. The volume can be increased in the playback mode or in other modes.

As described above, the classification logic 104 can detect simple single-touch gestures, such as a touch, tap, or double tap of the device, as illustrated in FIG. 7. Normally multiple antennas and detection circuits would be needed to detect touches in multiple locations of the device. However, as described herein, the classification logic 104 can also recognize multiple touches at different locations over time for additional touch events or gesture events, including swipe gestures, using the SPMT antenna 110. FIG. 8 to FIG. 22 describe how the classification logic 104 can classify multiple touches over time for touch events or gesture events using an SPMT antenna.

FIG. 8 illustrates multiple unique touch points 804 identified on and around an antenna aperture of an SPMT antenna 800, according to at least one embodiment. The SPMT antenna 800 can be similar to the SPMT antenna 110 of FIG. 1. The SPMT antenna can include a design that creates a set of N unique touch points 804, called virtual buttons or touch locations, where N is greater than one (BN(BN={B1, B2, B3, . . . . BN}). The touch points 804 are represented as circles in FIG. 8. The size and shape of the antenna aperture 802 can vary. As illustrated in FIG. 8, the touch points 804 can be located within the antenna aperture 802, such as the touch points 806a-806d, or around the antenna aperture 802, such as touch points 806e-806f. The touch points 804 correspond to different regions of the SPMT antenna 800. Touching or taping on each of these touch points 804 (Bn locations) of the SPMT antenna 800 can generate N unique time varying output signals denoted as sn (t)={s1 (t), s2 (t), s3 (t), . . . , sN (t)}. Since any user gesture is a time varying event, the number of mapped action items can be extended beyond N, by observing the change in output signal s(t) for a period of time, provided each generated response is unique. The following describes some examples of touch events and swipe gestures.

A single tap touch event on any of Bn={B1, B2, B3, . . . , BN} buttons will generate a single occurrence, sn (t), out of a set of N individual unique touch responses {s1(t), s2(t), s3(t), . . . , sN(t)}. The time duration of these signals is characteristic of the touch. Although this time duration does depend on many factors, including the behavior of each user, a “nominal” tap duration is approximately 150 msec. However, there are applications for which longer time durations are either required, or desired.

A multiple tap touch event on any of Bn={B1, B2, B3, . . . , BN} buttons similarly will produce unique responses which will be a repetition of sn (t)={s1 (t), s2 (t), s3 (t), . . . , sN (t)} in time. For example, a user may tap three times B1, and one time B2. The resultant response would be a signal consisting of the sequence of s1(t), s1(t), s1(t), and s2(t); displaced in accord to the times that the user executes each tap.

A combination tap touch event in which two or more buttons are touched simultaneously from Bn={B1, B2, B3, . . . , BN}, will produce unique responses. That is, for example, touching simultaneously B1 and B2 will create a unique signal response, say s12 (t), etc.

A tap and hold touch event on any of of Bn={B1, B2, B3, . . . , BN} buttons similarly will produce unique responses which will time-stretched versions of the corresponding signals sn (t)={s1(t), s2(t), s3(t), . . . , sN(t)} described above.

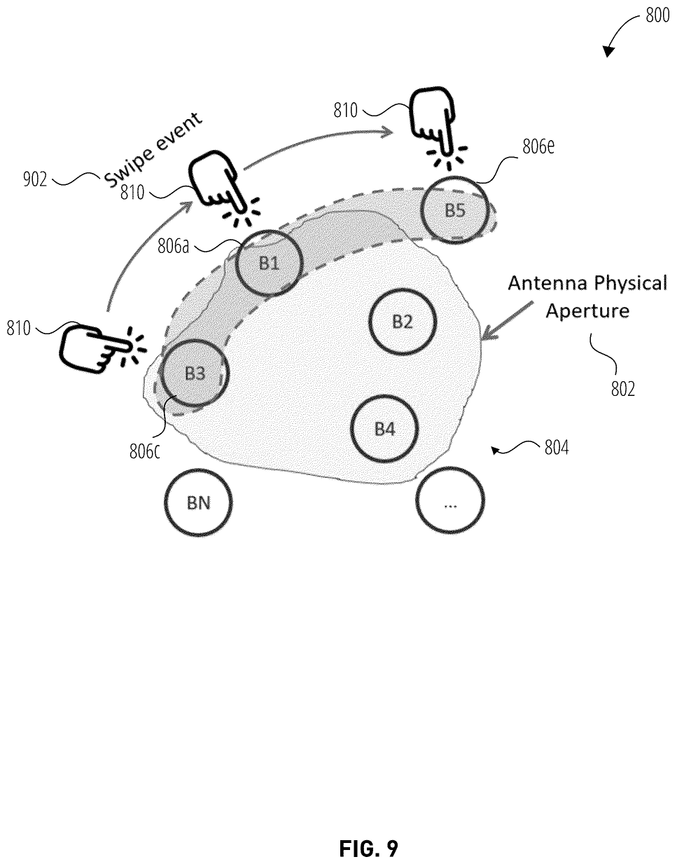

Any complex swipe gesture can be detected as a time-series of two or more unique touch events, such as illustrated in FIG. 9, where an object 810 (e.g., the user's finger) traverses M touch points in a sequential manner (where M>=2). Concomitantly, the output of the detection circuit will be a time series response containing a subset of {s1(t), s2(t), s3(t), . . . , sN(t)} in a particular order. The processing device 102 can read the sequence/order of the detected output signals, classify the sequence/order of the detected output signals using the classification logic, and finally map the sequence to a pre-defined action item.

Any such unique touch gestures mentioned above can be mapped to different actions performed by the processing device 102.

FIG. 9 illustrates an example directional swipe event 902 between multiple touch points 804 according to at least one embodiment. The directional swipe event 902 is detected a time-series or sequence of three unique touch events, where the object 810 traverses the three touch points 806c, 806a, and 806e in a sequential manner. Concomitantly, the output of the detection circuit will be a time series response containing a subset of {s1(t), s2(t), s3(t), . . . , sN(t)} in a particular order (e.g., {s3(t), s1(t), s5 (t)}). The processing device 102 can read the sequence/order of the detected output signals, classify the sequence/order of the detected output signals using the classification logic, and finally map the sequence to a pre-defined action item corresponding to the directional swipe event 902.

To distinguish touch points 804 for touch events or gesture events, the processing device 102 can perform multi-frequency monitoring. For multi-frequency monitoring, the processing device 102 can sample the output voltage signal s(t) from the detection circuit at multiple frequency points. The output signal, s(t), is sampled during normal communication transmissions of the radio. Depending on the radio, certain transmissions may be easier to handle for the purpose of gesture detection. As an example, the radio 106 can be a Bluetooth Low Energy (BLE) radio, and the processing device 102 samples the output signal 114 s(t) during the advertising transmissions at the three advertising channels (i.e. channel 37:2402 MHz, channel 38:2426 MHz and channel 39:2480 MHz). The temporal behavior of s(t) at these three individual channels {s37, s38, s39} are used to first establish a baseline (indicating that the user is not interacting with the device). In particular, it is assumed that in the overwhelming majority of times, the antenna of the device is not touched. Gestures are relatively short events. The baseline is determined by the long duration response, while the gestures are detected from short-term variations to the baseline.

During any touch gesture, the output signal 114 of {s37, s38, s39} will change from the respective baseline data. The touch points 804 can be uniquely classified/identified by monitoring the voltage change polarity and magnitude from the baseline value at these three channels. When swipe gestures are performed, they are recognized by tracking the trajectory from one touch point to another over time, by comparing the output voltage variation at the said frequency points. The choice and number of sampling frequency points can be decided based on the radio protocols and how many unique touch buttons (or the number of gestures) needs to be identified. The higher the number of virtual buttons the more complex is the detection procedure, and thus more sampling frequency points monitoring may be required. The classification logic 104, which can implement a dedicated classification algorithm pre-loaded in the processing device 102 (e.g., SoC) classifies the touch/swipe events based on the s(t) value at the sampling frequency points and maps them to different action items for the device according to a certain pre-agreed etiquette.

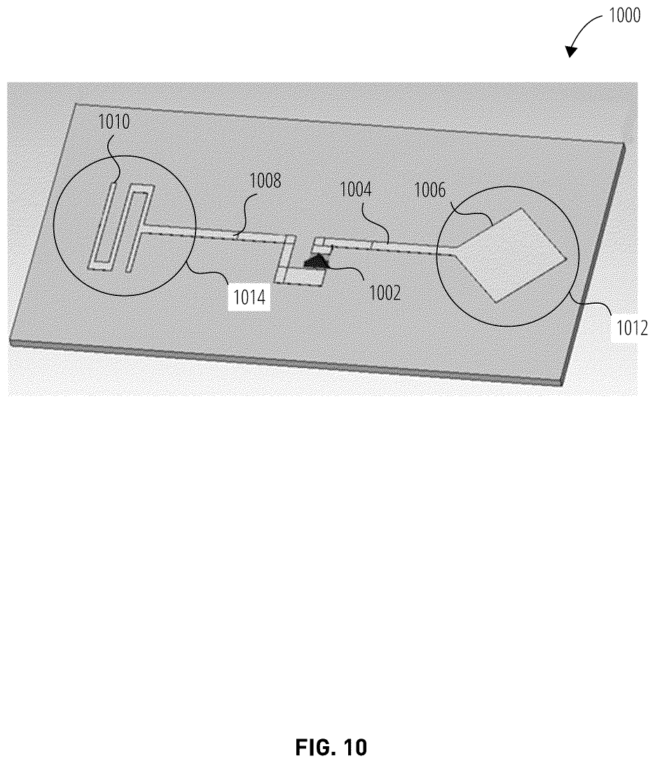

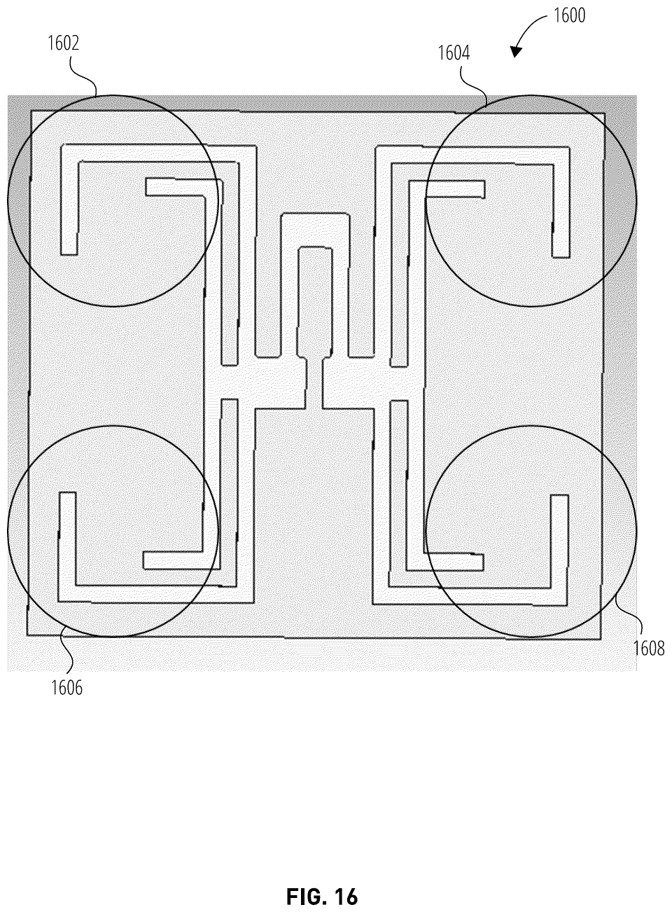

As described herein, the multi-frequency monitoring works in connection with the characteristics of the SPMT antenna 800. The main characteristic of suitable antenna designs for the SPMT antenna 800 is that their input impedance exhibit distinct behavior when they are touched (i.e. dielectrically loaded) at distinct touch points. The SPMT antenna 800 can have different physical attributes that contribute to the input impedance exhibiting distinct behaviors when they are touched at distinct touch points. The SPMT antenna 800 can be a dipole, a loop, a slot, a planar inverted F antenna (PIFA), a multi-mode antenna, or the like. A few design examples of the SPMT antenna 800 (or SPMT antenna 110 of FIG. 1) are described herein and illustrated in FIG. 10-FIG. 12, and FIG. 16-FIG. 20.

FIG. 10 illustrates an example single dipole antenna 1000 with end asymmetries according to at least one embodiment. The single dipole antenna 1000 includes a first arm 1004 with a first end 1006 and a second arm 1008 with a second end 1010, the first end 1006 and the second end 1010 being asymmetric in shape and size. The end asymmetries can create favorable charge distribution towards the dipole ends. The end asymmetries provides touch-sensitive end points with a noticeable difference from point to point in the impedance characteristics of the single dipole antenna 1000 when touched at the two end points. The two end points correspond to two touch points, including first touch point 1012 and second touch point 1014. This designed difference can be detected by the classification logic and allows the assignment of different commands/actions to the second touch point 1014 and first touch point 1012.

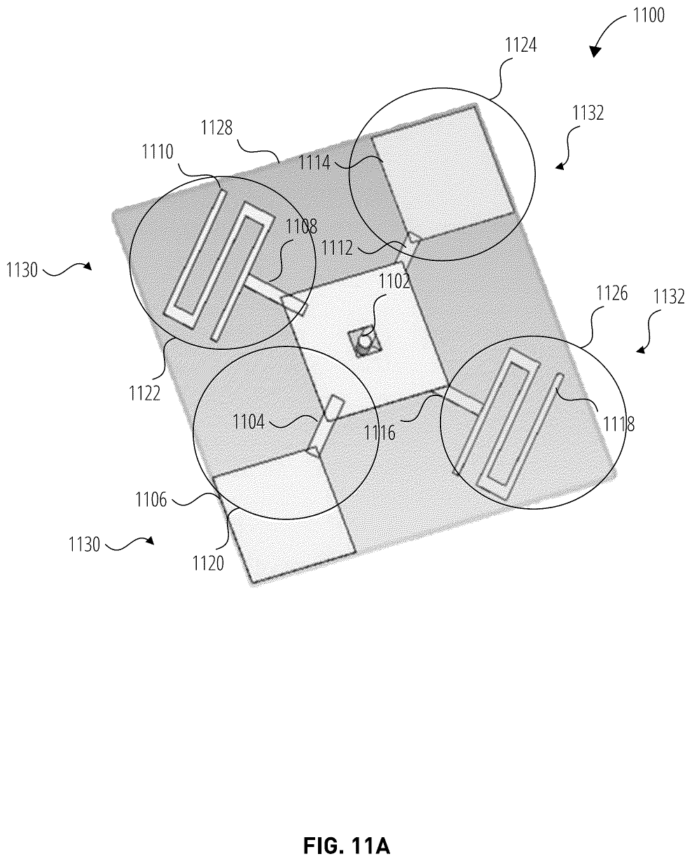

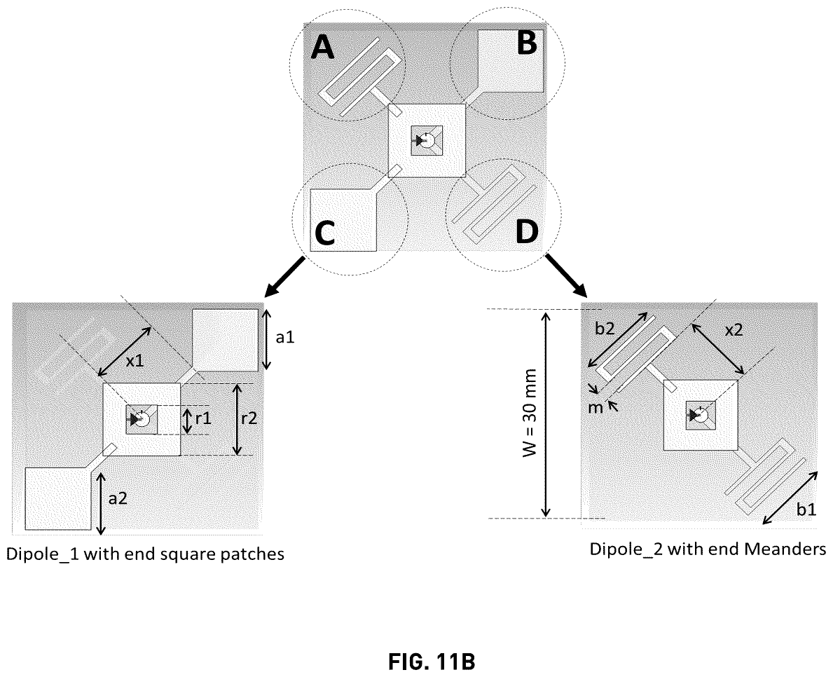

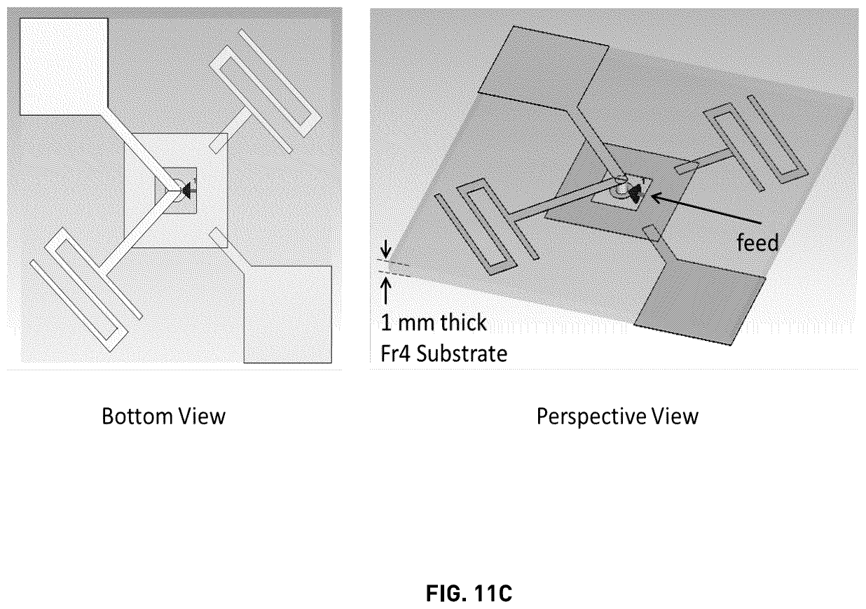

In another embodiment, the SPMT antenna can be a single-feed dipole structure with more than two arms (also referred to as branches or elements), such as illustrated in the two-layer, cross-dipole antenna 1100 with end asymmetries of FIG. 11A.

FIG. 11A-FIG. 11C illustrate an example two-layer, cross-dipole antenna 1100 with end asymmetries according to at least one embodiment. The two-layer, cross-dipole antenna 1100 includes a first arm 1104 with a first end 1106 and a second arm 1108 with a second end 1110 located on a first layer 1130 of a circuit board 1128. The two-layer, cross-dipole antenna 1100 also includes a third arm 1112 with a third end 1114 and a fourth arm 1116 with a fourth end 1118 located on a second layer 1132 of the circuit board 1128. The first end 1106 and the second end 1110 are asymmetric in shape and size. The third end 1114 and the fourth end 1118 are asymmetric in shape and size. The first end 1106 and the third end 1114 are asymmetric in terms of being located on different layers of the circuit board 1128. The second end 1110 and the fourth end 1118 are asymmetric in terms of being located on different layers of the circuit board 1128. The end asymmetries (shape, size, location) can create favorable charge distribution towards the dipole ends. The end asymmetries provides at least four touch-sensitive end points with a noticeable difference from point to point in the impedance characteristics of the two-layer, cross-dipole antenna 1100 when touched at the four end points. The four end points correspond to four touch points, including first touch point 1120, second touch point 1122, third touch point 1124, and fourth touch point 1126. In other embodiments, additional touch points can correspond to additional regions of the two-layer, cross-dipole antenna 1100, such as a touch point assigned to a region corresponding to the single feed point 1102. This designed difference can be detected by the classification logic and allows the assignment of different commands/actions to the first touch point 1120, second touch point 1122, third touch point 1124, and fourth touch point 1126.

In this embodiment, the arms of the dipoles (e.g., branches) can be similar in shape and dimensions. In other embodiments, the arms of the dipoles can differ in dimensions or shape. In other embodiments, additional elements can be located in different layers of the circuit board 1128.

In at least one embodiment, the two-layer, cross-dipole antenna 1100 can be implemented on a 1 mm thick FR4 substrate. In other embodiments, the two-layer, cross-dipole antenna 1100 can be printed on flex material depending on the required conformality of the gesture area. The two-layer, cross-dipole antenna 1100 includes two orthogonal dipoles excited simultaneously from the single feed point 1102, hence the name cross dipole (also referred to as X-dipole).

FIG. 11B illustrates different views of the example two-layer, cross-dipole antenna of FIG. 11A with end asymmetries according to at least one embodiment. Any conventional dipole antenna when excited in its fundamental mode accumulates opposite polarity charges at the two ends of the dipole, hence generating a time-varying half-sinusoid charge distribution. When a user finger comes in close proximity to these high density charge distribution areas, it influences (may divert or accumulate) the instantaneous charge distribution depending on the distance from the finger, and hence capable of changing the instantaneous antenna impedance. Thus, a simple dipole antenna in its fundamental mode possesses two touch sensitive regions separated by ˜λ/2 (where λ is the operating wavelength). At a BLE center operating frequency (2.45 GHZ), λ/2 is approximately ˜61 mm in freespace condition. In practical implementation, considering the antenna substrate and loading from its environment (housing material, chassis, printed circuit boards (PCBs), etc., the half-wavelength @2.45 GHz will be in the range of approximately ˜30-50 mm which reasonable for a human finger to differentiate between two different touch points.

In this embodiment, the two-layer, cross-dipole antenna 1100 combines two dipoles orthogonally to create four potential touch sensitive zones at their end points (represented by four circled sensitive touch regions (A, B, C, D) by superimposing two dipole structures orthogonally onto same FR4 substrate within an example footprint of 30 mm×30 mm.

The two-layer, cross-dipole antenna 1100 can be visualized as a combination of two separate dipole structures partially distributed on two sides of the substrate, including:
a. Dipole_1 with square patches at the two ends (characterized by parameters: a1, a2, x1)
b. Dipole_2 with meander structures at the two ends (characterized by parameters: b1, b2, m, x2)

The use of square patches, as compared to meandering lines (also referred to as meanders) at the dipole ends facilitates asymmetry in the dipole design, which is required to create different charge distribution on Dipole_1 ends vs Dipole_2 ends. There are many other possible asymmetric patterns can be envisioned to create different charge distribution, such as, comb structure, ring structure, etc. In other embodiments, the annular square ring at the center (characterized by parameters: r1, r2) provides a common grounding strip for both Dipole_1 and Dipole_2. There is a via at the center of the antenna which connects the bottom conducting layer to the top conducting layer. The annular square ring also provides additional degrees of freedom to create different possible arrangements for antenna excitation (not illustrated in FIG. 11A). The phase and magnitude of the excitation seen by the Dipole_1 vs Dipole_2 depends on which edge of the annular is chosen for grounding the antenna cable, thus it helps in diversifying the antenna current distribution and different mode generations.

FIG. 11C illustrates a bottom view and a perspective view of an example two-layer, cross-dipole antenna with end asymmetries according to at least one embodiment. As described herein, different physical attributes can be achieved by the placement of elements of the SPMT antenna on different layers of a circuit board. As illustrated in FIG. 11B, the two-layer, cross-dipole antenna can have a patch element and a meander structure on a first layer, as shown in the bottom view. Also, as illustrated in FIG. 11B, the two-layer, cross-dipole antenna can have another patch element and another meander structure on a second layer. The distance between the layers can be used to differentiate the signal fingerprints at the four touch points as described herein. Also, the placement of the circuit board relative to the housing can also provide different distances between the elements and the housing. This physical distances from the elements to the housing can be used to differentiate between touching different areas of the SPMT antenna.

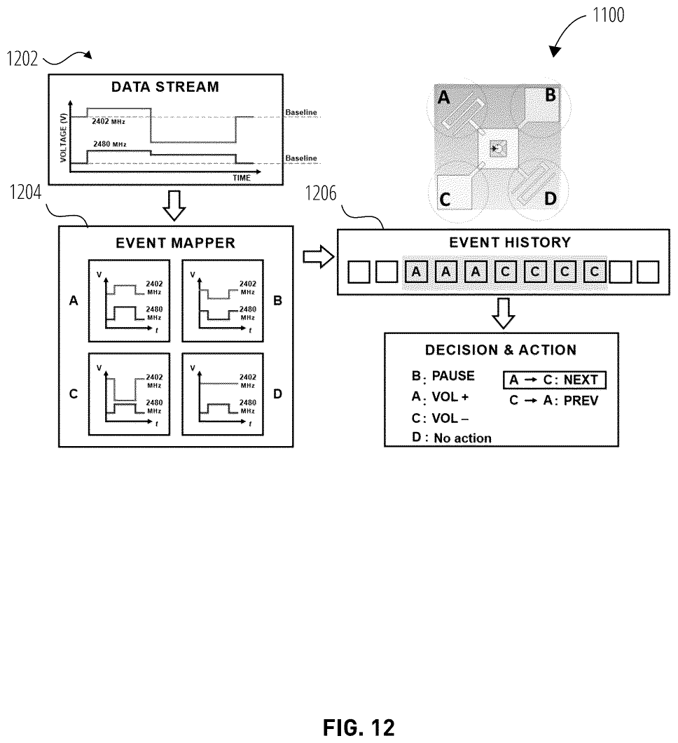

FIG. 12 illustrates example data streams that are fed into an event mapper and stored in an event history for the two-layer, cross-dipole antenna 1100 of FIG. 11A with four virtual buttons according to at least one embodiment. In at least one embodiment, the classification logic implements a classification algorithm which compares drift in ADC voltage from a baseline value (voltage levels and sign) at different frequencies, at a certain time intervals. As described herein, the output signal can be sampled at multiple frequencies into a data stream 1202 with two channels (e.g., high and low channels). The data stream 1202 can indicate a magnitude and a polarity relative to a baseline value in the respective channel. In the illustrated example, the data stream 1202 is tracked at a low channel (e.g., channel 37:2402 MHz) and a high channel (e.g., channel 39:2480 MHz), which is then passed to an event mapper 1204 to detect which virtual button was touched. In particular, the classification logic can receive the data stream 1202 and use an event mapper 1204 to map a portion of the data stream 1202 into a touch event, such as virtual button A is touched.

The event mapper 1204 can store an indication of each touch event into an event history buffer 1206. The event history records the order of occurrence for the touch events which is then used to decide the type of gesture performed by the user. At least two buffer samples can be tracked between any two consecutive touch event detection. The classification logic can use the event history buffer 1206 to determine a touch event or a gesture event. For example, as illustrated in FIG. 12, the event history buffer 1206 can include a touch event of three touches of the virtual button A, followed by four touches of the virtual button C. The classification logic can determine that this sequence of touch events over a period of time corresponds to gesture event associated with a first action, such as play a next audio file. In other examples, the event history buffer 1206 can indicate that the virtual button B has been touched over a period of time corresponding to a touch event associated with a second action, such as “pausing” an audio file from playback.

In at least one embodiment, the two-layer, cross-dipole antenna 1100 is integrated within a top housing a device, such as a smart speaker device. The classification logic can map three virtual buttons (A, B, C) to five different gestures for five different action items, such as set forth below:
1. single touch/tap on B to play/pause audio tracks.
2. touch and hold A to increase volume. (e.g.: For every 0.5 second of hold on A will increase the volume level by 10% of the full limit.)
3. touch and hold C to decrease volume. (e.g.: For every 0.5 second of hold on C will decrease the volume level by 10% of the full limit.)
4. SWIPE down, A→C: go to next audio track
5. SWIPE up, C→A: go to previous audio track

In other embodiments, other number of virtual buttons can be defined and other number of corresponding touch or gesture events can be defined for different combinations of touches and gestures.

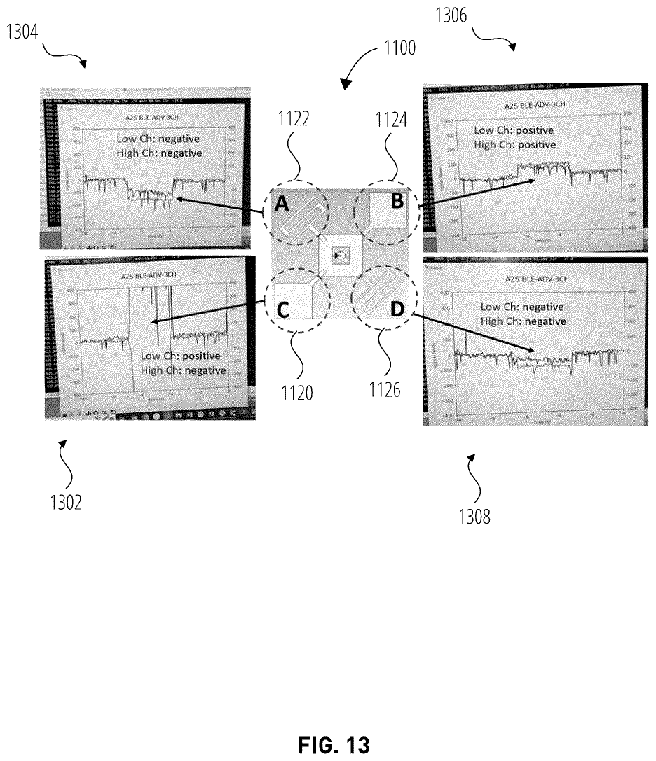

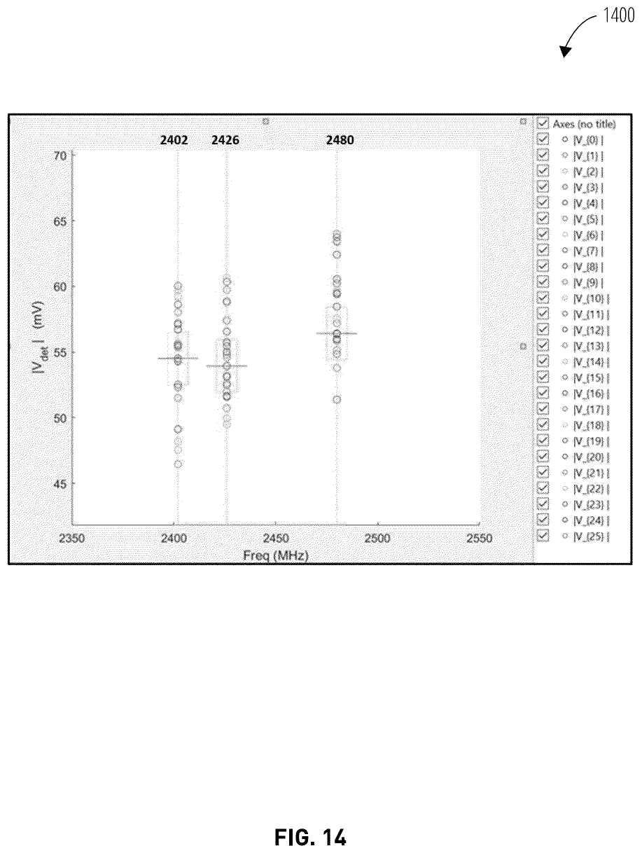

FIG. 13 illustrates ADC responses for single touch events at four virtual buttons (A, B, C, D) according to at least one embodiment. In this embodiment, the ADC responses are monitored at a first channel (low channel) and a second channel (high channel). For example, the first and second channels are two BLE advertisement channels, including channel 37 at 2402 MHz (low channel) and channel 39 at 2480 MHz (high channel). In a first ADC response 1302, the low channel is a positive response above a baseline and the high channel is a negative response below the baseline. In a second ADC response 1304, the low channel is a negative response below the baseline and the high channel is a negative response below the baseline. In a third ADC response 1306, the low channel is a positive response above the baseline and the high channel is a positive response above the baseline. In a fourth ADC response 1308, the low channel is a negative response below the baseline and the high channel is a negative response below the baseline. The classification logic can detect the differences between the ADC responses to identify a position of the touch. When the classification logic detects the first ADC response 1302, the classification logic can output an indication of the first touch point 1120 being touched (e.g., virtual button C). Similarly, when the classification logic detects the second ADC response 1304, the classification logic can output an indication of the second touch point 1122 being touched (e.g., virtual button A). Similarly, when the classification logic detects the third ADC response 1306, the classification logic can output an indication of the third touch point 1124 being touched (e.g., virtual button B). Similarly, when the classification logic detects the fourth ADC response 1308, the classification logic can output an indication of the fourth touch point 1126 being touched (e.g., virtual button D). Although the second and fourth ADC responses are similar in both channels having a negative response, the second ADC response 1304 and the fourth ADC response 1308 can be differentiated in magnitude to differentiate between the second touch point 1122 being touched and the fourth touch point 1126 being touched. As illustrated in FIG. 13, all four virtual buttons when touched, generate clearly distinguishable voltage drift from baseline data on two channels. In some embodiments, three channels can be used. A simple classification algorithm can be applied to map these ADC responses to A/B/C/D touch events, such as using the following Equation (1):

$${V}_{TT} = \{ \begin{matrix}+ 3 ; & Δ {V}_{m} > + 3 {V}_{thr} \\ + 2 ; & + 2 {V}_{thr} < Δ {V}_{m} < + 3 {V}_{thr} \\ + 1 ; & + {V}_{thr} < Δ {V}_{m} < + 2 {V}_{thr} \\ 0 ; & \vert Δ {V}_{m} \vert < {V}_{thr} \\ - 1 ; & - 2 {V}_{thr} < Δ {V}_{m} < - {V}_{thr} \\ - 2 ; & - 3 {V}_{thr} < Δ {V}_{m} < - 2 {V}_{thr} \\ - 3 ; & Δ {V}_{m} < - 3 {V}_{thr}\end{matrix} \qquad ( 1 )$$

where Vthr is the threshold voltage (e.g., Vthr=2 mV), which is the minimum analog voltage drift that can be measured with certainty by the ADC on the processing device (e.g., by the ADC pin on an SoC). In this example, the classification logic can be focused on the variation of the output signal at three BLE advertising channels (i.e. channel 37:2402 MHZ, channel 38:2426 MHz and channel 39:2480 MHz). The classification logic can track the deviations of output data (|Vn|) from the baseline data (|V0|) at these three channels as shown in a graph 1300 of FIG. 14.

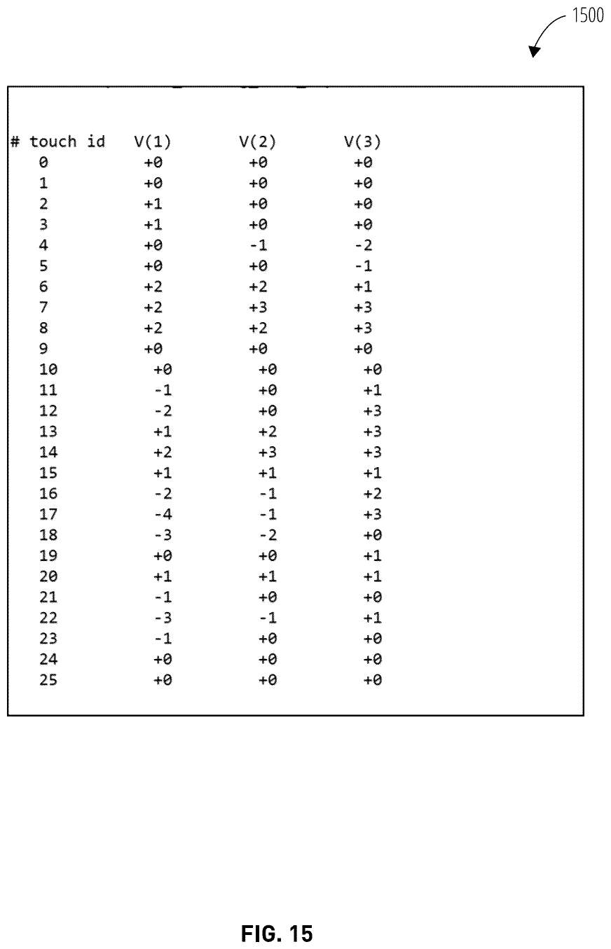

FIG. 14 illustrates a graph 1400 tracking deviations of output data (|Vn|) from baseline data |V0| at three channels according to at least one embodiment. The classification logic can use a Truth Table by quantizing the drift in voltage compared to baseline, i.e, ΔVm=|Vn|−|V0|, as defined above in equation (1). An example of the Truth Table is illustrated in FIG. 15.

FIG. 15 illustrates an example Truth Table 1500 with the quantized voltage levels (VTT) at three channels for twenty-five touch configurations according to at least one embodiment. The Truth Table 1500 lists the VTT at three BLE advertising channels (V(1), V(2), V(3)). The first row in the Truth Table 1500 is the baseline data (|V0|). As expected, for each touch event (touch events 1→25), the |V| plot deviates from the baseline data.

As described herein, other antenna designs with different regions having different physical attributes can be used to distinguish between multiple touch points of the SPMT antenna. Some examples are illustrated and described below with respect to FIG. 16 to FIG. 20.

FIG. 16 illustrates an example dual dipole butterfly antenna 1600 with arm asymmetries according to at least one embodiment. The dual dipole butterfly antenna 1600 has asymmetric arm lengths which are intended to generate resonances at multiple frequency bands. In some cases, multiple touch positions, like touch point 1602, touch point 1604, touch point 1606, and touch point 1608, can change the antenna input impedance enough to be differentiated by the classification logic. This designed difference can be detected by the classification logic and allows the assignment of different commands/actions to the touch point 1602, touch point 1604, touch point 1606, and touch point 1608.

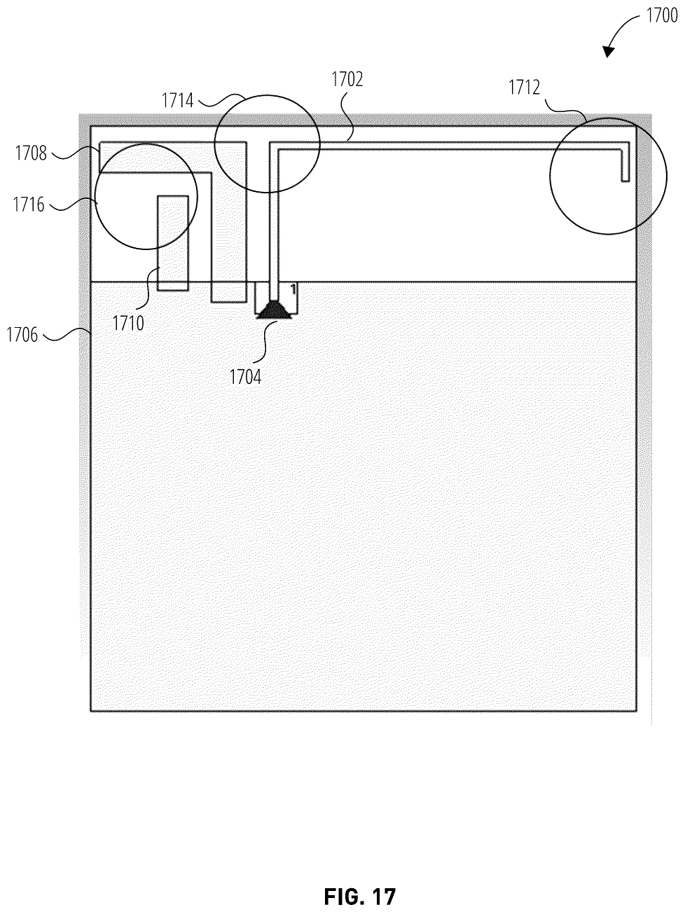

FIG. 17 illustrates an example single-feed gap-reconfigurable PIFA structure 1700 with induced gaps according to at least one embodiment. The single-feed gap-reconfigurable PIFA structure 1700 includes a radiating arm 1702 that is the main element of the single-feed gap-reconfigurable PIFA structure 1700. It is responsible for radiating and receiving electromagnetic waves. It is typically a flat, rectangular piece of conductive material (such as metal) located a small distance above a ground plane 1706. The radiating arm 1702 can also be of various shapes, including truncated or with slits, to achieve different performance characteristics or to fit within physical constraints. The ground plane 1706 serves as a reference point for the single-feed gap-reconfigurable PIFA structure 1700 and affects its radiation pattern and impedance. It is usually a flat, conductive surface that the radiating arm 1702 is parallel to. In many devices, the device's own circuit board or a portion of it acts as the ground plane 1706. The radiating arm 1702 is coupled to a single feed point 1704. The single feed point 1704 is where the single-feed gap-reconfigurable PIFA structure 1700 is connected to an RF feed line, bringing in the signal to be transmitted or sending out the received signal. The position of the single feed point 1704 on the radiating arm 1702 significantly influences the antenna's impedance and resonance frequency. The single-feed gap-reconfigurable PIFA structure 1700 can include parasitic structures, such as parasitic element 1708 and parasitic element 1710 separated by small gaps. Upon touching the gap area with an object (e.g., user's finger), the parasitic structures are coupled to the single-feed gap-reconfigurable PIFA structure 1700, thus effectively reconfiguring the single-feed gap-reconfigurable PIFA structure 1700. This gap-induced reconfiguration changes the antenna input impedance, which is detectable by the classification logic. The parasitic element 1708 and parasitic element 1710 provide asymmetries in the single-feed gap-reconfigurable PIFA structure 1700 that provide touch-sensitive touch points with a noticeable difference from point to point in the impedance characteristics of the single-feed gap-reconfigurable PIFA structure 1700 when touched at different touch points. Two or more touch points can be differentiated using the single-feed gap-reconfigurable PIFA structure 1700. In some cases, multiple touch positions, like first touch point 1712, second touch point 1714, and third touch point 1716, can change the antenna input impedance enough to be differentiated by the classification logic. This designed difference can be detected by the classification logic and allows the assignment of different commands/actions to the first touch point 1712, second touch point 1714, and third touch point 1716.

In another embodiment, the SPMT antenna can be a single-feed dipole structure with more than two arms (also referred to as branches or elements), such as illustrated in the two-layer, cross-dipole antenna 1100 with end asymmetries of FIG. 11A.

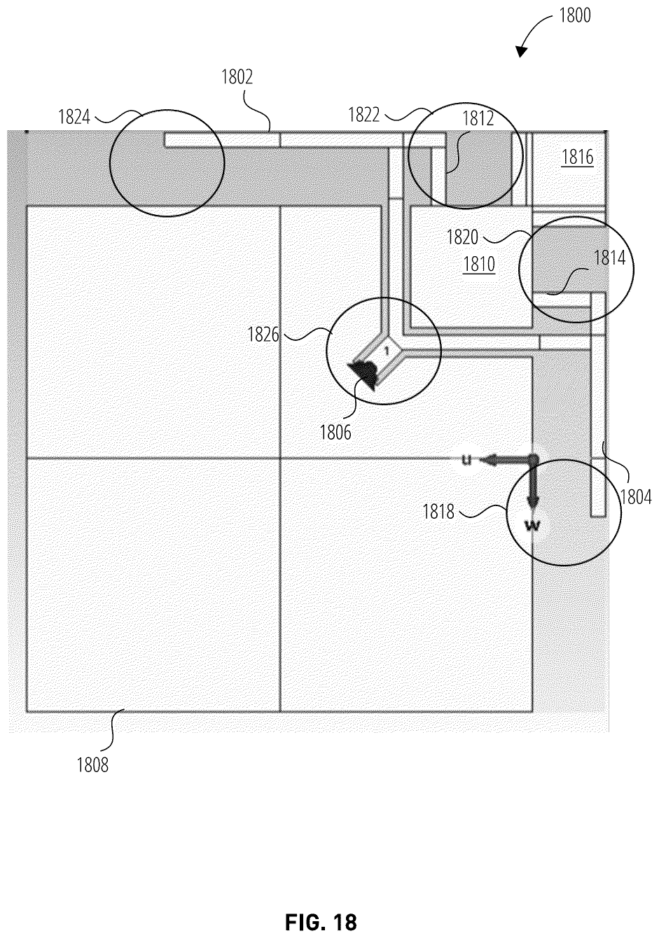

FIG. 18 illustrates an example single-feed, two orthogonal PIFA structure 1800 with induced gaps according to at least one embodiment. The single-feed, two orthogonal PIFA structure 1800 includes a first radiating arm 1802 located a small distance above a ground plane 1808 on a first side of the ground plane 1808 and a second radiating arm 1804 located a small distance above the 1808 on a second side of the ground plane 1808. The first radiating arm 1802 and the second radiating arm 1804 are coupled to a single feed point 1806. The single feed point 1806 is where the single-feed, two orthogonal PIFA structure 1800 is connected to an RF feed line, bringing in the signal to be transmitted or sending out the received signal. A first shorting pin 1812 is coupled between the first radiating arm 1802 and a ground parasitic element 1816. A second shorting pin 1814 is coupled between the second radiating arm 1804 and the parasitic element 1816. The ground metal element 1810 can be a portion of the ground plane 1808 or a separate piece of metal. The ground plane 1808 and ground metal element 1810 are both at the same ground potential. The single-feed, two orthogonal PIFA structure 1800 can include one or more parasitic structures, such as a parasitic element 1816 that creates a first gap between the parasitic element 1816 and the first radiating arm 1802 and a second gap between the parasitic element 1816 and the second radiating arm 1804. Upon touching the gap areas with an object (e.g., user's finger), the parasitic structures are coupled to the single-feed, two orthogonal PIFA structure 1800, thus effectively reconfiguring the single-feed, two orthogonal PIFA structure 1800. This gap-induced reconfiguration changes the antenna input impedance, which is detectable by the classification logic. In particular, the one or more parasitic structures or the induced gaps change the impedance in response to the presence of the object in proximity to the one or more parasitic structures or the induced gaps. The parasitic element 1816 and the gaps between provide asymmetries in the single-feed, two orthogonal PIFA structure 1800 that provide touch-sensitive touch points with a noticeable difference from point to point in the impedance characteristics of the single-feed, two orthogonal PIFA structure 1800 when touched at different touch points. Two or more touch points can be differentiated using the single-feed, two orthogonal PIFA structure 1800. This designed difference can be detected by the classification logic and allows the assignment of different commands/actions to the different touch points. In some cases, multiple touch positions, like touch point 1818, touch point 1820, touch point 1822, touch point 1824, and touch point 1826, can change the antenna input impedance enough to be differentiated by the classification logic. This designed difference can be detected by the classification logic and allows the assignment of different commands/actions to the touch point 1818, touch point 1820, touch point 1822, touch point 1824, and touch point 1826.

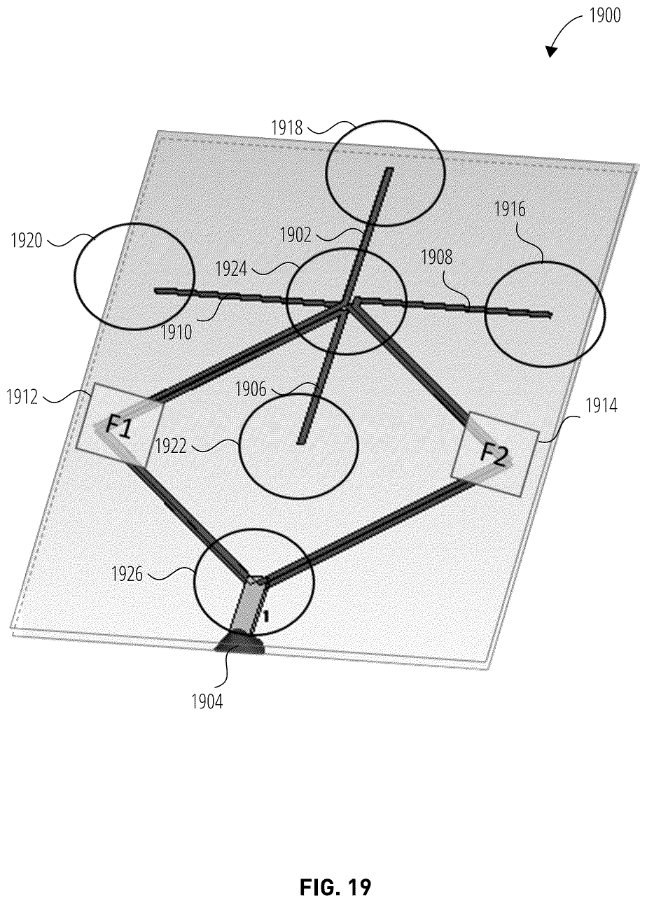

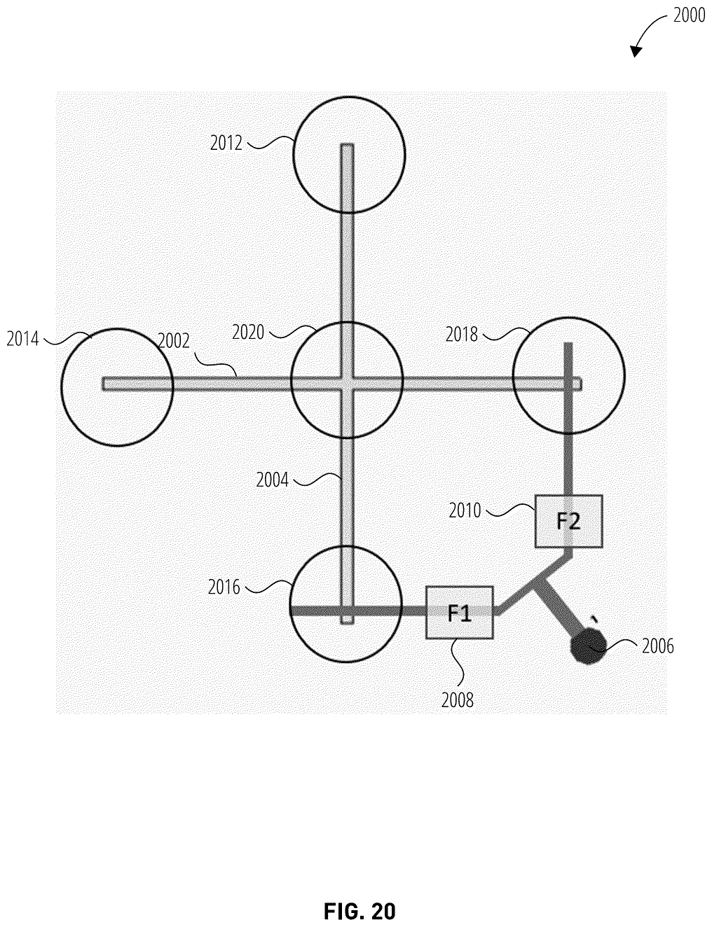

In another embodiment, the SPMT antenna can be a single-feed, two orthogonal dipole structure or slot structure with filters to provide asymmetries, such as illustrated in the single-feed, two orthogonal dipole structure 1900 of FIG. 19 and the single-feed, two orthogonal slot structure 2000 of FIG. 20.

FIG. 19 illustrates an example single-feed, two orthogonal dipole structure 1900 with filters according to at least one embodiment. In this category of suitable antenna designs, two orthogonal dipoles are fed simultaneously from a single port. In particular, a first arm 1902 and a second arm 1908 are coupled to a single feed point 1904. The first arm 1902 extends in a zig-zag pattern on a first layer of a circuit board. An additional segment 1906 is coupled to the first arm 1902 and is located on a second layer of the circuit board. The second arm 1908 extends in a zig-zag pattern on the first layer of the circuit board. An additional segment 1910 is coupled to the second arm 1908 and is located on the second layer of the circuit board. A first filter 1912 is added to a feedline of the first arm 1902, and a second filter 1914 is added to a feedline of the second arm 1908. The first filter 1912 and second filter 1914 can control the individual dipole resonances, thus creating multi-modal antenna designs. The additional segment 1906 and additional segment 1910 also provide additional asymmetries with respect to the first arm 1902 and the second arm 1908. It should be noted that the two dipole structures are implemented as a dual-layer antenna, traces on both layers. In some cases, multiple touch positions, like touch point 1916, touch point 1918, touch point 1920, touch point 1922, touch point 1924, and touch point 1926, can change the antenna input impedance enough to be differentiated by the classification logic. This designed difference can be detected by the classification logic and allows the assignment of different commands/actions to the touch point 1916, touch point 1918, touch point 1920, touch point 1922, touch point 1924, and touch point 1926.

FIG. 20 illustrates an example single-feed, two orthogonal slot structure 2000 with filters according to at least one embodiment. In this category of suitable antenna designs, two orthogonal slots are fed simultaneously from a single port. In particular, a first slot 2002 and a second slot 2004 are fed by a single feed point 2006. The first slot 2002 extends in a first direction, and the second slot 2004 extends in a second direction orthogonal to the first direction. A first filter 2008 is added at a specific location of the first slot 2002, and a second filter 2010 is added to a specific location of the second slot 2004. The first filter 2008 and second filter 2010 can control the individual slot resonances, thus creating multi-modal antenna designs. In some cases, multiple touch positions, like touch point 2012, touch point 2014, touch point 2016, touch point 2018, and touch point 2020, can change the antenna input impedance enough to be differentiated by the classification logic. This designed difference can be detected by the classification logic and allows the assignment of different commands/actions to the touch point 2012, touch point 2014, touch point 2016, touch point 2018, and touch point 2020.

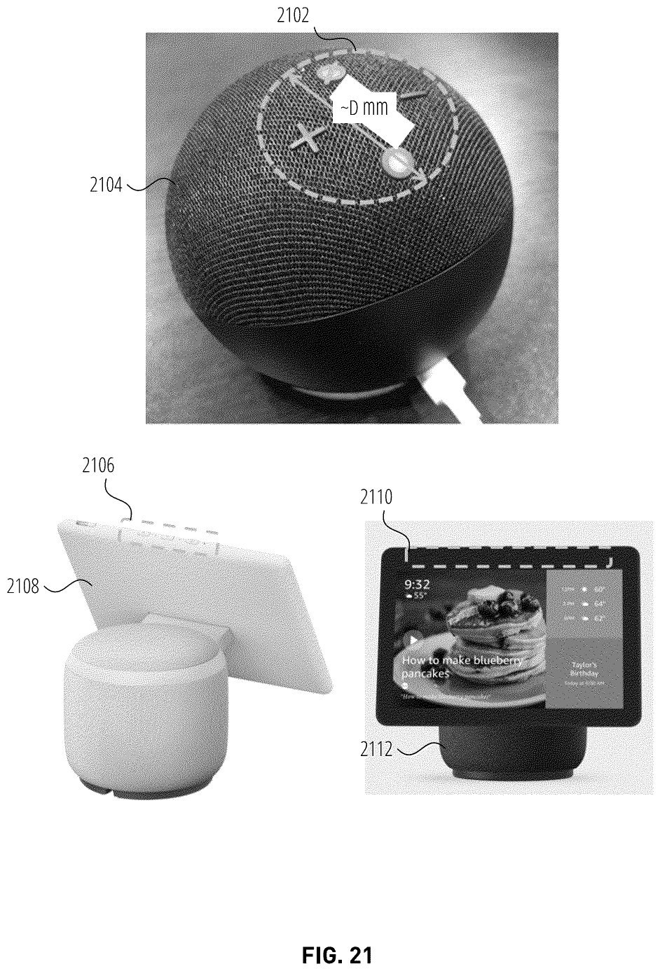

The purpose of an antenna in a radio system is to communicate with other radios at relatively far distances. So, antennas are typically placed at such a location on a device so that they can radiate efficiently and be manufacturable at an appropriate cost. The SPMT antenna, as described herein, serves an additional purpose, which is to sense user fingers proximate to the SPMT antenna. Considering that, the SPMT antenna should to be placed at a location on the device which is ergonomically convenient to perform different gestures with fingers. The SPMT antenna can be integrated right under the inner layer of external housing, so that the gap between antenna surface and user finger stays within couple of millimeter to ensure strong output signals s(t), such as illustrated in various embodiments of FIG. 21, for performing touch/swipe gestures.

FIG. 21 show a few examples of ergonomically suitable areas for placement of an SPMT antenna according to various embodiment. In at least one embodiment, the SPMT antenna can be located right under an inner layer of an external housing in a first area 2102 of a first wireless device 2104. The first area 2102 can be located at a top of a dome of the first wireless device 2104. The SPMT antenna can replace one or more capacitive or mechanical push buttons that would otherwise be located in the first area 2102.

In at least one embodiment, the SPMT antenna can be located right under an inner layer of an external housing in a second area 2106 of a second wireless device 2108. The second area 2106 can be located in a top edge of a display of the second wireless device 2108. The SPMT antenna can replace one or more capacitive or mechanical push buttons that would otherwise be located in the second area 2106.

In at least one embodiment, the SPMT antenna can be located behind a glass at a top portion in a third area 2110 of a third wireless device 2112. Alternatively, the SPMT antenna can be located behind a glass on a side portion of the screen (not labeled in FIG. 21). The third area 2110 can be located in the top outer rim of the display to enable smooth touch/swipe gestures as if part of the display.

It should be noted that the conceptualization of an SPMT antenna can start with considering certain design requirements, such as the following:
1. how many unique gesture detection is required? and in turn how many virtual touch buttons are required (N) to achieve those gestures?
2. What is the preferred layout of the virtual buttons on the device surface that will give best customer experience while performing different gestures? This will in turn define the required physical extent of the SPMT antenna aperture, which is also primarily depends on the operating frequency. The higher the frequency the smaller the antenna footprint.
3. Considering average human fingertip size varying in the range ˜ 10-15 mm diameter, any two neighboring virtual buttons should have adequate physical separation from each other to minimize overlap of their touch sensitive regions.

For example, the first area 2102 of the first wireless device 2104 can have a specified diameter of D (e.g., 50 mm) where normally four capacitive push buttons are located in a diamond shape, namely Mute, Volume Up, Action, Volume Down. The SPMT antenna can be located in this same area and have three or four virtual buttons defined. The housing can have labels that identify where the user should touch for the respective action items.

In at least one embodiment, an electronic device includes an antenna, a detection circuit coupled to the antenna, and a wireless radio coupled to the antenna. The electronic device also includes one or more processors and one or more computer readable media storing processor executable instructions which, when executed using the one or more processors, cause the electronic device to perform operations including, determining, based on a signal received from the detection circuit, a first voltage value for a first time corresponding to wireless transmission at a first frequency channel using the wireless radio and the antenna, determining, based on a signal received from the detection circuit, a second voltage value for a second time corresponding to wireless transmission at a second frequency channel using the wireless radio and the antenna, determining, based on the first voltage value and the second voltage value, a user input event, and based on the determining of the user input event, executing an action.

In a further embodiment, the one or more computer readable media store processor executable instructions which, when executed using the one or more processors, cause the electronic device to perform operations further including determining, based on a signal received from the detection circuit, a third voltage value for a third time corresponding to wireless transmission at a third frequency channel using the wireless radio and the antenna. The determining of the user input event is based on the third voltage value.

In at least one embodiment, the electronic device includes an analog-to-digital converter. The operation of determining of the first voltage value and the determining of the second voltage value utilizes the analog-to-digital converter. In at least one embodiment, the first voltage value is a value that was sampled using the analog-to-digital converter from a signal received from the detection circuit.

In at least one embodiment, the operations further include determining, based on a signal received from the detection circuit, a first plurality of voltage values associated with wireless transmission at the first frequency channel using the wireless radio and the antenna, determining, based on a signal received from the detection circuit, a second plurality of voltage values associated with wireless transmission at the first frequency channel using the wireless radio and the antenna. The operation of determining of the user input event is based on the first plurality of voltage values and the second plurality of voltage values.

In at least one embodiment, the operations further include determining, based on a signal received from the detection circuit, a third voltage value for a third time corresponding to wireless transmission at a third frequency channel using the wireless radio and the antenna. The operation of determining of the user input event is based on the third voltage value.

In at least one embodiment, the operations further include generating, based on a signal received from the detection circuit and using an analog-to-digital converter, a plurality of voltage values each associated with a timestamp.

In at least one embodiment, the user input event represents a touch event or double tap event. In at least one embodiment, the user input event represents a swipe event. In at least one embodiment, the user input event represents a multi-touch event corresponding to multiple simultaneous user touches.

In at least one embodiment, the operations further include determining first data representing a magnitude and polarity of difference between the first voltage value and a baseline voltage value. The operation of determining of the user input event is based on the first data.

In at least one embodiment, the operations further include determining, based on a signal received from the detection circuit, a first plurality of voltage values associated with wireless transmission at the first frequency channel using the wireless radio and the antenna, the first plurality of voltage values including the first voltage value, determining, based on a signal received from the detection circuit, a second plurality of voltage values associated with wireless transmission at the first frequency channel using the wireless radio and the antenna, the second plurality of voltage values including the second voltage value, providing the first plurality of voltage values and the second plurality of voltage values to a machine learning model. In at least one embodiment, the operation of determining the user input event is based on the providing of the first plurality of voltage values and the second plurality of voltage values to the machine learning model.

In at least one embodiment, the operations further include determining, based on a signal received from the detection circuit, a first plurality of voltage values associated with wireless transmission at the first frequency channel using the wireless radio and the antenna, the first plurality of voltage values including the first voltage value, determining, based on a signal received from the detection circuit, a second plurality of voltage values associated with wireless transmission at the first frequency channel using the wireless radio and the antenna, the second plurality of voltage values including the second voltage value. The operation of determining the user input event is based on deterministic logic taking as input the first plurality of voltage values and the second plurality of voltage values.

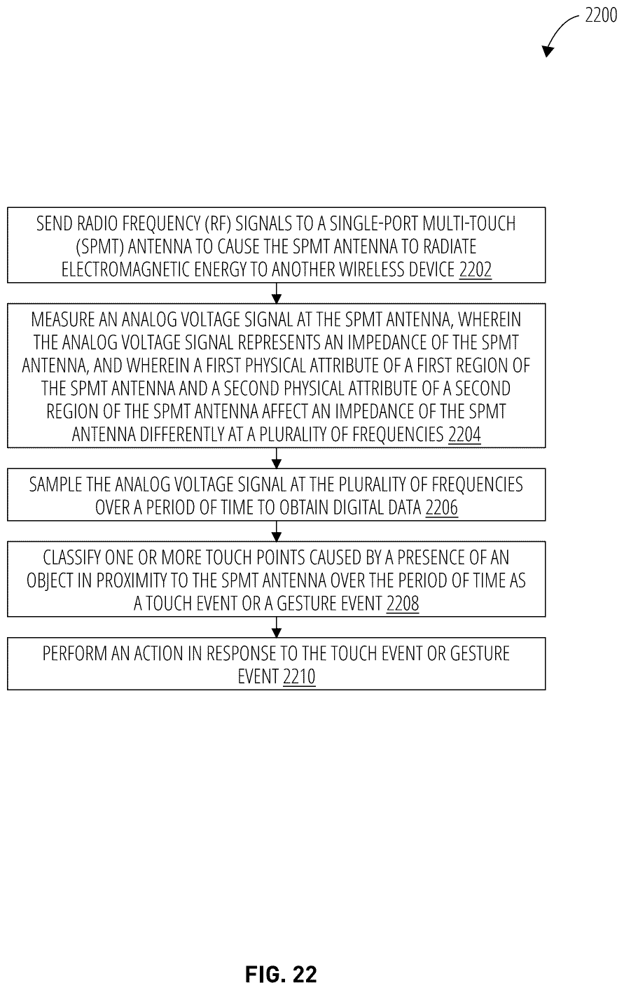

FIG. 22 is a flow chart of a method 2200 of detecting a touch or gesture event according to at least one embodiment. The method 2200 may be performed by processing logic that may comprise hardware (e.g., circuitry, dedicated logic, programmable logic, microcode, etc.), software (e.g., instructions run on a processing device to perform hardware simulation), or a combination thereof. In one embodiment, the method 2200 is performed by the wireless device 100 of FIG. 1. In one embodiment, the method 2200 is performed by the first wireless device 2104, second wireless device 2108, or third wireless device 2112 of FIG. 21. The method 2200 can be performed by other devices described herein.

Referring to FIG. 22, the method 2200 begins with the processing logic sending radio frequency (RF) signals to a single-port multi-touch (SPMT) antenna to cause the SPMT antenna to radiate electromagnetic energy (block 2202). At block 2204, processing logic measures an analog voltage signal at the SPMT antenna. The analog voltage signal represents an impedance of the SPMT antenna. A first physical attribute of a first region of the SPMT antenna and a second physical attribute of a second region of the SPMT antenna affect an impedance of the SPMT antenna differently at a plurality of frequencies. At block 2206, the processing logic samples the analog voltage signal at the plurality of frequencies over a period of time to obtain digital data. At block 2208, the processing logic classifies one or more touch points caused by a presence of an object in proximity to the SPMT antenna over the period of time as a touch event or a gesture event. At block 2210, the processing logic performs an action in response to the touch event or gesture event.

In at least one embodiment, at block 2208, the processing logic compares a drift in magnitude and polarity of the sampled analog voltage signal from a baseline value at each of the plurality of frequencies. The processing logic determines a set of one or more touches at one or more of a plurality of touch points from the comparing the drift in magnitude and polarity of the sampled analog voltage signal from the baseline value. The processing logic determines a type of event, comprising the touch event or the gesture event, from an order of occurrence for the set of one or more touches.

In at least one embodiment, at a third time before the first time and the second time, the processing logic establishes a baseline representing that the object is not in proximity to the SPMT antenna at each of the plurality of frequencies. The processing logic can determine a touch event or a gesture event by determining that the voltage relative to a threshold amount.

In at least one embodiment, the processing logic, at block 2206, samples the analog voltage signal at the plurality of frequencies at a first time to obtain first digital data and at a second time to obtain second digital data. The processing logic, at block 2208, the processing logic determines, using the first digital data, a first touch, caused by the object, at a first position at the first time, the first position corresponding to the first region of the SPMT antenna. The processing logic determines, using the second digital data, a second touch, caused by the object, at a second position at the second time, the second position corresponding to the second region of the SPMT antenna. The processing logic classifies the first touch as the gesture event. The action corresponds to the gesture event.

In at least one embodiment, the processing logic, at block 2206, samples the analog voltage signal at the plurality of frequencies at a first time to obtain first digital data and at a second time to obtain second digital data. The processing logic, at block 2208, the processing logic determines, using the first digital data, a first touch, caused by the object, at a first position at the first time, the first position corresponding to the first region of the SPMT antenna. The processing logic determines, using the second digital data, that the first touch remains at the first position at the second time. The processing logic classifies the first touch as the touch event. The action corresponds to the touch event.

In at least one embodiment, the processing logic measures the first voltage by diverting a portion of power (e.g., current) from a first path between a radio and the SPMT antenna to a second path with a detection circuit. The processing logic measures, using the detection circuit, amplitude variations of the first RF signal using the portion of power. The processing logic outputs a voltage waveform representing the amplitude variations, wherein the voltage waveform represents changes in impedance. The processing logic converts the voltage waveform into digital data comprising the first voltage and the second voltage.

In at least one embodiment, the processing logic sends the first RF signal in an advertising channel of a WPAN protocol. In at least one embodiment, the processing logic sends the first RF signal in a first advertising channel of a WPAN protocol. The processing logic sends the second RF signal in a second advertising channel of the WPAN protocol.

In at least one embodiment, the processing logic, a third time before the first time and the second time, the processing logic establishes a baseline representing that the object is not in proximity to the SPMT antenna. The processing logic determines that the change in impedance exceeds the baseline by a threshold amount. The threshold amount above or below the baseline is the criterion.

In at least one embodiment, the processing logic detects an amount of reflected power in the first path. The processing logic converts the amount of reflected power to a voltage waveform. The amount of reflected power in the first path varies in response to changes in impedance of the SPMT antenna. The processing logic converts, using an ADC, the voltage waveform into digital data.

In at least one embodiment, the actions can include starting an audio file, stopping an audio file, pausing playback of the audio file, resuming playback of the audio file, changing playback of a subsequent audio file in a list or a previous audio file in the list, increasing a volume, or decreasing the volume. In at least one embodiment, the touch event is at least one of a tap, a double tap, a tap and hold, or a palm tap and hold. Alternatively, other touch or hover events can be detected.

The embodiments described herein explains a new methodology of realizing multiple touch buttons, and directional swipe gestures from a single antenna design of an wireless device with existing radio. This embodiments described herein does not require additional hardware, instead it teaches advanced antenna design techniques to add additional functionalities of an antenna in addition to the conventional wireless transmission/reception of signals. This embodiments described herein demonstrate how to create multiple touch sensitive points on/around the antenna to accomplish Time Varying Gesture Detection by utilizing the existing radio transmissions of the wireless devices.

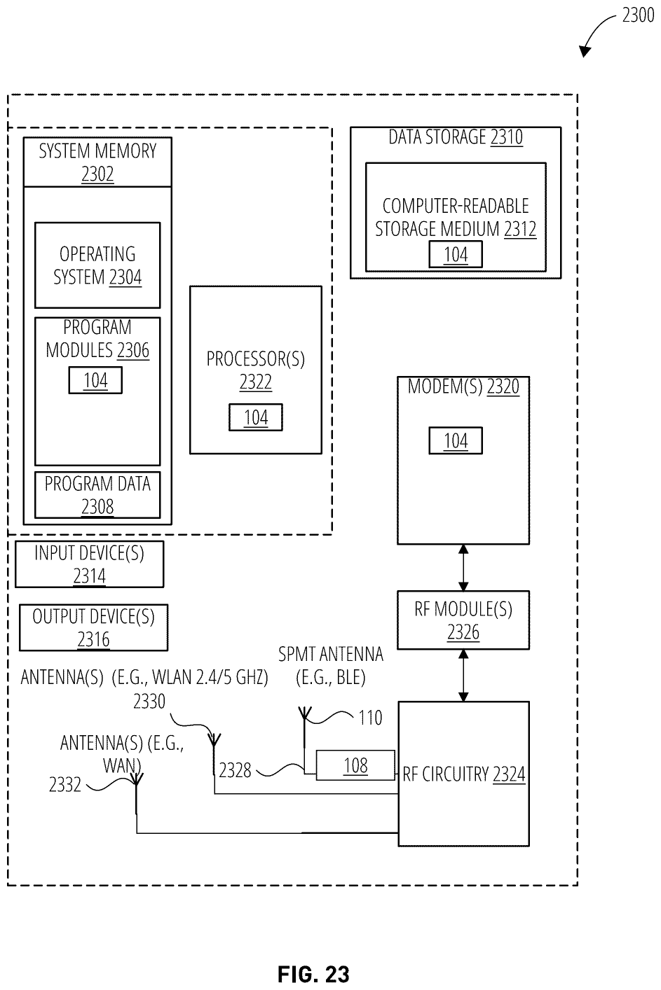

FIG. 23 is a block diagram of a wireless device 2300 with classification logic 104 and a detection circuit 108 according to one embodiment. The wireless device 2300 may correspond to any devices described above with respect to FIG. 1 to FIG. 22. In the depicted embodiment, the wireless device 2300 includes the classification logic 104 and detection circuit 108. Alternatively, the wireless device 2300 may be other electronic devices, as described herein.

The wireless device 2300 includes one or more processor(s) 2322, such as one or more CPUs, microcontrollers, field-programmable gate arrays, or other types of processors. The wireless device 2300 also includes system memory 2302, which may correspond to any combination of volatile and/or non-volatile storage mechanisms. The system memory 2302 stores information that provides operating system component 2304, various program modules 2306, program data 2308, and/or other components. In one embodiment, the system memory 2302 stores instructions of methods to control the operation of the wireless device 2300. The wireless device 2300 performs functions by using the processor(s) 2322 to execute instructions provided by the system memory 2302. In one embodiment, the program modules 2306 may include the classification logic 104 described herein. The classification logic 104 may perform some of the operations for detection gestures, touch events, hover events, or the like, as described herein.

The wireless device 2300 also includes a data storage device 2310 that may be composed of one or more types of removable storage and/or one or more types of non-removable storage. The data storage device 2310 includes a computer-readable storage medium 2312 on which is stored one or more sets of instructions embodying any of the methodologies or functions described herein. Instructions for the program modules 2306 (e.g., classification logic 104) may reside, completely or at least partially, within the computer-readable storage medium 2312, system memory 2302, and/or within the processor(s) 2322 during execution thereof by the wireless device 2300, the system memory 2302 and the processor(s) 2322 also constituting computer-readable media. The wireless device 2300 may also include one or more input device(s) 2314 (keyboard, mouse device, specialized selection keys, etc.) and one or more 2316 (displays, printers, audio output mechanisms, etc.).

The wireless device 2300 further includes one or more modem(s) 2320 to allow the wireless device 2300 to communicate via wireless connections (e.g., such as provided by the wireless communication system) with other computing devices, such as remote computers, an item providing system, and so forth. The modem(s) 2320 can be connected to one or more radio frequency (RF) modules 2326. The RF modules 2326 may be a WLAN module, a WAN module, a wireless personal area network (WPAN) module, a Global Positioning system (GPS) module, or the like. The SPMT antenna 110, and other antenna(s) 2330 and 2332 are coupled to the RF circuitry 2324, which is coupled to the modem(s) 2020. The SPMT antenna 110 is coupled to the detection circuit 108. The RF circuitry 2324 may include radio front-end circuitry, antenna switching circuitry, impedance matching circuitry, or the like. The SPMT antenna 110 can be a PAN antenna (e.g., BLE). The antenna(s) 2330, 2332 may be GPS antennas, a near field communication (NFC) antennas, other WAN antennas, WLAN or PAN antennas, or the like. The modem(s) 2320 allows the wireless device 2300 to handle both voice and non-voice communications (such as communications for text messages, multimedia messages, media downloads, web browsing, etc.) with a wireless communication system. The modem(s) 2320 may provide network connectivity using any type of mobile network technology including, for example, cellular digital packet data (CDPD), general packet radio service (GPRS), EDGE, universal mobile telecommunications system (UMTS), 1 times radio transmission technology (1×RTT), evaluation data optimized (EVDO), high-speed downlink packet access (HSDPA), Wi-Fi®, Long Term Evolution (LTE) and LTE Advanced (sometimes generally referred to as 4G), etc.

The modem(s) 2320 may generate signals and send these signals to the SPMT antenna 110 of a first type (e.g., BLE), antenna(s) 1230 of a second type (e.g., WLAN 2.4 GHZ), and/or antenna(s) 1232 of a third type (e.g., WAN), via RF circuitry 2424, and RF module(s) 2326 as described herein. SPMT antenna 110 and antenna(s) 2330, 2332 may be configured to transmit in different frequency bands and/or using different wireless communication protocols. The SPMT antenna 110, antenna(s) 2330, 2332 may be directional, omnidirectional, or non-directional antennas. In addition to sending data, SPMT antenna 110, antenna(s) 2330, 2332 may also receive data, which is sent to appropriate RF modules connected to the antennas. The antenna 110 may be any combination of the SPMT antenna structures described herein.

In one embodiment, the wireless device 2300 establishes a first connection using a first wireless communication protocol, and a second connection using a different wireless communication protocol. The first wireless connection and second wireless connection may be active concurrently, for example, if a wireless device is receiving a media item from another wireless device (e.g., a mini-POP node) via the first connection) and transferring a file to another electronic device (e.g., via the second connection) at the same time. Alternatively, the two connections may be active concurrently during wireless communications with multiple devices. In one embodiment, the first wireless connection is associated with a first resonant mode of an SPMT antenna structure that operates at a first frequency band and the second wireless connection is associated with a second resonant mode of the SPMT antenna structure that operates at a second frequency band. In another embodiment, the first wireless connection is associated with a first SPMT antenna structure and the second wireless connection is associated with a second SPMT antenna. In other embodiments, the first wireless connection may be associated with content distribution within mesh nodes of a wireless mesh network and the second wireless connection may be associated with serving a content file to a client consumption device, as described herein.

In the above description, numerous details are set forth. It will be apparent, however, to one of ordinary skill in the art having the benefit of this disclosure, that embodiments may be practiced without these specific details. In some instances, well-known structures and devices are shown in block diagram form rather than in detail in order to avoid obscuring the description.

Some portions of the detailed description are presented in terms of algorithms and symbolic representations of operations on data bits within a computer memory. These algorithmic descriptions and representations are the means used by those skilled in the data processing arts to convey the substance of their work most effectively to others skilled in the art. An algorithm is used herein and is generally conceived to be a self-consistent sequence of steps leading to the desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “determining,” “sending,” “receiving,” “scheduling,” or the like, refer to the actions and processes of a computer system, or similar electronic computing device, that manipulates and transforms data represented as physical (e.g., electronic) quantities within the computer system's registers and memories into other data similarly represented as physical quantities within the computer system memories or registers or other such information storage, transmission or display devices.

Embodiments also relate to an apparatus for performing the operations herein. This apparatus may be specially constructed for the required purposes, or it may comprise a general-purpose computer selectively activated or reconfigured by a computer program stored in the computer. Such a computer program may be stored in a computer-readable storage medium, such as, but not limited to, any type of disk including floppy disks, optical disks, Read-Only Memories (ROMs), compact disc ROMs (CD-ROMs), and magnetic-optical disks, Random Access Memories (RAMs), EPROMs, EEPROMs, magnetic or optical cards, or any type of media suitable for storing electronic instructions.

The algorithms and displays presented herein are not inherently related to any particular computer or other apparatus. Various general-purpose systems may be used with programs in accordance with the teachings herein, or it may prove convenient to construct a more specialized apparatus to perform the required method steps. The required structure for a variety of these systems will appear from the description below. In addition, the present embodiments are not described with reference to any particular programming language. It will be appreciated that a variety of programming languages may be used to implement the teachings of the present embodiments as described herein. It should also be noted that the terms “when” or the phrase “in response to,” as used herein, should be understood to indicate that there may be intervening time, intervening events, or both before the identified operation is performed.

It is to be understood that the above description is intended to be illustrative, and not restrictive. Many other embodiments will be apparent to those of skill in the art upon reading and understanding the above description. The scope of the present embodiments should, therefore, be determined with reference to the appended claims, along with the full scope of equivalents to which such claims are entitled.

What is claimed is:

1. A wireless device comprising:
a processing device comprising an analog-to-digital converter (ADC) and classification logic;
a radio coupled to the processing device;
a single-port multi-touch (SPMT) antenna coupled to the radio, the SPMT antenna to receive radio frequency (RF) signals from the radio and radiate electromagnetic energy to another wireless device, wherein a first physical attribute of a first region of the SPMT antenna and a second physical attribute of a second region of the SPMT antenna affect an impedance of the SPMT antenna differently at a plurality of frequencies; and
a detection circuit coupled between the radio and the SPMT antenna, the detection circuit to output an analog voltage signal to the ADC of the processing device, the analog voltage signal representing the impedance of the SPMT antenna, wherein:
the ADC is to sample the analog voltage signal at the plurality of frequencies at a first time to obtain first digital data;
the classification logic is to determine, using the first digital data, that a presence of an object in proximity to the SPMT antenna is located at a first position corresponding to the first region of the SPMT antenna;
the ADC is to sample the analog voltage signal at the plurality of frequencies at a second time to obtain second digital data;
the classification logic is to determine, using the second digital data, that the presence of the object in proximity to the SPMT antenna is located at a second position corresponding to the second region of the SPMT antenna; and
the classification logic is to determine a gesture event using the first position and the second position; and
the processing device is to perform an action in response to the gesture event.

2. The wireless device of claim 1, wherein the SPMT antenna comprises at least one of i) a single-feed gap-reconfigurable planar inverted F antenna (PIFA) structure comprising one or more parasitic structures separated by gaps, or ii) a single-feed, two orthogonal PIFA structure with induced gaps, wherein the one or more parasitic structures or the induced gaps change the impedance in response to the presence of an object in proximity to the one or more parasitic structures or the induced gaps.

3. The wireless device of claim 1, wherein the SPMT antenna comprises at least one of
i) a dipole antenna with asymmetries in at least one of arms of the dipole antenna or ends of the dipole antenna;
ii) a single-feed, two orthogonal dipole with filters; or
iii) a single-feed, two orthogonal slot structure with filters,
wherein the filters control individual resonances of the ii) or iii).

4. An electronic device comprising:
an antenna;
a detection circuit coupled to the antenna;
a wireless radio coupled to the antenna;
one or more processors;
one or more computer readable media storing processor executable instructions which, when executed using the one or more processors, cause the electronic device to perform operations comprising
determining, based on a signal received from the detection circuit, a first voltage value for a first time corresponding to wireless transmission at a first frequency channel using the wireless radio and the antenna,
determining, based on a signal received from the detection circuit, a second voltage value for a second time corresponding to wireless transmission at a second frequency channel using the wireless radio and the antenna,
determining, based on the first voltage value and the second voltage value, a user input event,
based on the determining of the user input event, executing an action.

5. The electronic device of claim 4, wherein the electronic device comprises an analog-to-digital converter, and wherein the determining of the first voltage value and the determining of the second voltage value utilize the analog-to-digital converter.

6. The electronic device of claim 4, wherein the electronic device comprises an analog-to-digital converter, and wherein the first voltage value is a value that was sampled using the analog-to-digital converter from a signal received from the detection circuit.

7. The electronic device of claim 4, wherein the one or more computer readable media store processor executable instructions which, when executed using the one or more processors, cause the electronic device to perform operations comprising
determining, based on a signal received from the detection circuit, a third voltage value for a third time corresponding to wireless transmission at a third frequency channel using the wireless radio and the antenna;
wherein the determining of the user input event is based on the third voltage value.

8. The electronic device of claim 4, wherein the one or more computer readable media store processor executable instructions which, when executed using the one or more processors, cause the electronic device to perform operations comprising
determining, based on a signal received from the detection circuit, a first plurality of voltage values associated with wireless transmission at the first frequency channel using the wireless radio and the antenna;
determining, based on a signal received from the detection circuit, a second plurality of voltage values associated with wireless transmission at the first frequency channel using the wireless radio and the antenna;
wherein the determining of the user input event is based on the first plurality of voltage values and the second plurality of voltage values.

9. The electronic device of claim 4, wherein the one or more computer readable media store processor executable instructions which, when executed using the one or more processors, cause the electronic device to perform operations comprising
determining, based on a signal received from the detection circuit, a third voltage value for a third time corresponding to wireless transmission at a third frequency channel using the wireless radio and the antenna;
wherein the determining of the user input event is based on the third voltage value.

10. The electronic device of claim 4, wherein the one or more computer readable media store processor executable instructions which, when executed using the one or more processors, cause the electronic device to perform operations comprising
generating, based on a signal received from the detection circuit and using an analog-to-digital converter, a plurality of voltage values each associated with a timestamp.

11. The electronic device of claim 4, wherein the user input event represents a touch event or double tap event.

12. The electronic device of claim 4, wherein the user input event represents a swipe event.

13. The electronic device of claim 4, wherein the user input event represents a multi-touch event corresponding to multiple simultaneous user touches.

14. The electronic device of claim 4, wherein the one or more computer readable media store processor executable instructions which, when executed using the one or more processors, cause the electronic device to perform operations comprising
determining first data representing a magnitude and polarity of difference between the first voltage value and a baseline voltage value;
wherein the determining of the user input event is based on the first data.

15. The electronic device of claim 4, wherein the one or more computer readable media store processor executable instructions which, when executed using the one or more processors, cause the electronic device to perform operations comprising
determining, based on a signal received from the detection circuit, a first plurality of voltage values associated with wireless transmission at the first frequency channel using the wireless radio and the antenna, the first plurality of voltage values including the first voltage value;
determining, based on a signal received from the detection circuit, a second plurality of voltage values associated with wireless transmission at the first frequency channel using the wireless radio and the antenna, the second plurality of voltage values including the second voltage value;
providing the first plurality of voltage values and the second plurality of voltage values to a machine learning model;
wherein the determining the user input event is based on the providing of the first plurality of voltage values and the second plurality of voltage values to the machine learning model.

16. The electronic device of claim 4, wherein the one or more computer readable media store processor executable instructions which, when executed using the one or more processors, cause the electronic device to perform operations comprising
determining, based on a signal received from the detection circuit, a first plurality of voltage values associated with wireless transmission at the first frequency channel using the wireless radio and the antenna, the first plurality of voltage values including the first voltage value;
determining, based on a signal received from the detection circuit, a second plurality of voltage values associated with wireless transmission at the first frequency channel using the wireless radio and the antenna, the second plurality of voltage values including the second voltage value;
wherein the determining the user input event is based on deterministic logic taking as input the first plurality of voltage values and the second plurality of voltage values.

17. A method of operating a wireless device, the method comprising:
sending radio frequency (RF) signals to a single-port multi-touch (SPMT) antenna to cause the SPMT antenna to radiate electromagnetic energy to another wireless device;
measuring an analog voltage signal at the SPMT antenna, wherein the analog voltage signal represents an impedance of the SPMT antenna, and wherein a first physical attribute of a first region of the SPMT antenna and a second physical attribute of a second region of the SPMT antenna affect the impedance of the SPMT antenna differently at a plurality of frequencies;
sampling the analog voltage signal at the plurality of frequencies over a period of time to obtain digital data;
classifying one or more touch points caused by a presence of an object in proximity to the SPMT antenna over the period of time as a touch event or a gesture event; and
performing an action in response to the touch event or gesture event.

18. The method of claim 17, wherein classifying the one or more touch points as the touch event or the gesture event comprises:
comparing a drift in magnitude and polarity of the sampled analog voltage signal from a baseline value at each of the plurality of frequencies;
determining a set of one or more touches at one or more of a plurality of touch points from the comparing the drift in magnitude and polarity of the sampled analog voltage signal from the baseline value; and
determining a type of event, comprising the touch event or the gesture event, from an order of occurrence for the set of one or more touches.

19. The method of claim 17, wherein:
sampling the analog voltage signal comprises sampling the analog voltage signal at the plurality of frequencies at a first time to obtain first digital data and at a second time to obtain second digital data; and
classifying the one or more touch points as the touch event comprises:
determining, using the first digital data, a first touch, caused by the object, at a first position at the first time, the first position corresponding to the first region of the SPMT antenna;
determining, using the second digital data, that the first touch remains at the first position at the second time; and
classify the first touch as the touch event, wherein the action corresponds to the touch event.

20. The method of claim 17, wherein:
sampling the analog voltage signal comprises sampling the analog voltage signal at the plurality of frequencies at a first time to obtain first digital data and at a second time to obtain second digital data; and
classifying the one or more touch points as the gesture event comprises:
determining, using the first digital data, a first touch, caused by the object, at a first position at the first time, the first position corresponding to the first region of the SPMT antenna;
determining, using the second digital data, a second touch, caused by the object, at a second position at the second time, the second position corresponding to the second region of the SPMT antenna; and
classifying the first touch as the gesture event, wherein the action corresponds to the gesture event.
